(19) United States
(12) Patent Application Publication
(10) Pub. No.: US 2018/0375482 A1
(43) Pub. Date: Dec. 27, 2018

(54) ADAPTIVE-SNR ULTRA-LOW-POWER ULTRA-LOW-NOISE MICROPHONE

(71) Applicant: WIZEDSP LTD., Tel-Aviv (IL)

(72) Inventor: Oz GABAI, TEL-AVIV (IL)

(21) Appl. No.: 15/743,677

(22) PCT Filed: Jul. 12, 2016
(86) PCT No.: PCT/IB2016/054152

§ 371 Date: Jan. 11, 2018

Related U.S. Application Data
(60) Provisional application No. 62/191,452, filed on Jul. 12, 2015.

(51) Int. Cl. H03F 3/185; H03F 3/45; H02M 3/07; H04R 3/10; H04R 19/00; H04R 19/01; H04R 19/04

(52) U.S. Cl. CPC H03F 3/1855; H03F 3/45475; H02M 3/07; H04R 3/10; H04R 19/005; H04R 2410/03; H04R 19/04; H03F 2200/03; H03F 2200/102; H03F 2200/294; H04R 2201/003; H04R 19/01

(57) ABSTRACT

A microphone circuit including a JFET or MOSFET transistor, one input of an impedance network connected to the transistor's gate, a terminal of a source resistor connected to the transistor's source, another terminal of the source resistor connected to ground, a bypass capacitor connected in parallel to the source resistor, one terminal of a load resistor connected to the transistor's drain, VCC_LOW connected to another terminal of the load resistor, an input of an op-amplifier connected to the transistor's source through a bi-directional low-pass-filter, another input of the op-amplifier connected to reference voltage, an output of the op-amplifier connected to another terminal of the input impedance network through an LPF, an energy detector connected to the transistor's drain via a coupling capacitor, an LPF connected to the energy detector output, and an LPF connected to the output of the energy detector, the input impedance network connected to a microphone.

### CROSS-REFERENCE TO RELATED APPLICATIONS

This application claims the benefit of U.S. Provisional Application No. 62/191,452, filed Jul. 12, 2015, the disclosure of which is incorporated herein by reference in its entirety.

### FIELD

The method and apparatus disclosed herein are related to the field of electronic circuitry, and, more particularly, but not exclusively to systems and methods providing ultra-low-power and an ultra-low-noise microphone buffer having adaptive signal-to-noise ratio (SNR).

### BACKGROUND

Today, 2015, microphones are used nearly anywhere, in smartphones—where we have about 3 microphones for a smartphone, cellphones, Bluetooth earring devices, wired earring devices, toys, billions of microphones are sold every year. not only that, currently there are about 2 billion smartphones around the world, the smartphone, is basically a cellphone with internet connection palm computer and sensors, the smartphone keep each one of us to be connected to the internet, with “Google Play” for Android phones and “App Store” for iOS based phones, each one of us can download an application—for gaming, for Global Positioning System, for service providers etc., all in all the smartphone, which is connected to the internet and has the ability to run applications make our lives much more comfortable and easy.

In recent years more and more devices are being connected to the internet, such as air conditions, washing machines, clothes dryers, electrical water boilers. There are many advantages of connecting a device to the internet, for example connecting electrical water boiler, washing machine and clothes dryer machine, will help us to save money. The reason is that the rates of electricity depend on the time of the hour, usually in the morning time, residential electricity will cost less, since there is no much of demand, but at nights the residential electricity cost will be high because of two much of demand. Therefore one can activate the washing machine and drying machine in power saving mode, and the machines will contact the electricity utility company computer via the internet, and will get the rates as a function of time, then it would be possible to activate these machines only during low cost residential electricity rate.

With respect to air conditioners and smart sensors it is possible to have the “brain” of the air condition as a neural network on the internet, and hence activate it smartly, having many sensors around the house which are also connected to the internet.

Even further, it is possible to have a battery-based electricity generator, that will charge the battery when there is low demand—this may vary from time to time—and hence it is possible to get a generator that stores the electricity energy during low demand and hence during low rates and that would generate the energy at home during times where the rates are high—these battery based generator must be connected to the internet to be able to connect the electric utility company for getting the times when it is possible to charge the generator battery.

The above is called today the “Internet of Things” (IoT) or Internet of Everything (IoE). The benefits of connecting a device to the internet are:

Ability to smart control the device, having the brain on the net or the ability to control each device from our palm of our hands, Ability to monitor and get information about the device, for service for example, for off date usage, Ability to locate devices, Ability to have whole internet information in each device even a tooth brush or a screw driver, Ability to get deals, All on all, the connection of the devices to the internet will make our lives much more efficient, It is claimed that by 2020 more than 50,000,000,000 devices would be connected to the internet such as electrical devices: air-conditioners, drying machines, washing machine, battery-based generator, light bulbs, electricity outlets, electrical water boilers, gas-based water boilers, TV, Tools, such as screw driver or hammer, Bath related devices such as tooth brush and Bed room related devices.

It is clear that some IoT, or IoE devices that would be connected to the internet would have a local power source—such as electrical water boilers and air conditions—these IoT, IoE devices can use Wi-Fi, Bluetooth (BT), ZigBee or any other wireless standard or Power line to connect the device to the home local router and hence to the internet etc., but some devices such as glasses, tools, clothes, bath room moveable devices such as tooth brush, toys would not an energy source.

Therefore if implemented by electromagnetic radio frequency (RF) communication. Power is a big issue and such receiver would need to be implemented either as a periodically turn on/window turn on or as a wake receiver that basically detects a presence of energy in some band, and later check if it was valid marker. These two step process would usually save a lot of power, as the marker check is done only when a signal is detected.

However in the ISM band or in radio frequency band there is a lot of noise, and an implementation of selective band wakeup receiver is not an easy task with high bandwidth.

There is thus a widely recognized need for, and it would be highly advantageous to have, a system and method providing a microphone, and/or a microphone buffer circuit, devoid of the above limitations.

### SUMMARY

According to one exemplary embodiment there is provided a device and a method for a microphone including a JFET and MOSFET transistor, an impedance network, where a first input terminal of the impedance network is connected to a gate terminal of the transistor, a source resistor, where a first terminal of the source resistor is connected to a source terminal of the transistor, and a second terminal of the source resistor is connected to a ground terminal, a bypass capacitor (CS) connected in parallel to the source resistor, a load resistor (RD), where a first terminal of the load resistor is connected to a drain terminal of the transistor, a charge pump generating a low voltage power supply VCC_LOW and an inverted voltage −VEE, where the low voltage is connected to a second terminal of the load resistor, and the inverted voltage −VEE is connected to a first power supply node of an op-amplifier, an op-amplifier, where a first input terminal of the op-amplifier is connected to the source terminal of the transistor through a bi-directional low-pass-filter transistor, a second input terminal of the op-amplifier is connected to a controlled reference voltage Vref, a first power supply terminal of the op-amplifier is connected to the inverted voltage, a second supply terminal of the op-amplifier is connected to the main supply voltage, and an output terminal of the op-amplifier is connected to a second terminal of the input impedance network through a second low pass filter, and an input electrets capacitor source connected in parallel to the input impedance network, an ultra-low-power envelope/energy detector connected to drain terminal D of the transistor via coupling capacitor, a third low-pass-filter connected to the output of the ultra-low-power envelope/energy detector, and a fourth low-pass-filter connected to the output of the ultra-low-power envelope/energy detector.

According to another exemplary embodiment there is provided an SNR monitor including a first input connected to a third low-pass-filter output, a second input connected to a fourth low-pass-filter output, one of: a third analog input, and a third digital input, that determines the required SNR, a first output connected to a control input of a controlled Vref, and an optional second output connected to a control input of an optional controlled charge pump.

According to yet another exemplary embodiment there is provided a device and a method for a microphone including a transistor including at least one of a JFET and MOSFET transistor, an impedance network, where a first input terminal of the impedance network is connected to a gate terminal of the transistor, a source resistor, where a first terminal of the source resistor is connected to a source terminal of the transistor, and a second terminal of the source resistor is connected to a ground terminal, a bypass capacitor (CS) connected in parallel to the source resistor, a load resistor (RD), where a first terminal of the load resistor is connected to a drain terminal of the transistor, a charge pump generating a low voltage power supply VCC_LOW and an inverted voltage −VEE, where the low voltage is connected to a second terminal of the load resistor, and the inverted voltage −VEE is connected to a first power supply node of an op-amplifier, an op-amplifier, where a first input terminal of the op-amplifier is connected to the source terminal of the transistor through a bi-directional low-pass-filter transistor, a second input terminal of the op-amplifier is connected to a controlled reference voltage Vref, a first power supply of the op-amplifier terminal is connected to the inverted voltage, a second supply terminal of the op-amplifier is connected to the main supply voltage, and an output terminal of the op-amplifier is connected to a second terminal of the input impedance network through a second low pass filter, and an input source including a MEMS capacitor, where a first terminal of the MEMS capacitor is connected to ground, and a second terminal of the MEMS capacitor is connected to a first terminal of a MEMS bias network, the MEMS bias network, where a second terminal of the MEMS bias network is connected to a bias voltage VBB, and a coupling capacitor, where a first terminal of the coupling capacitor is connected to the second terminal of the MEMS capacitor, and with a second terminal of the coupling capacitor is connected to the gate terminal of the transistor, an ultra-low-power envelope/energy detector connected to drain terminal of the transistor via a coupling capacitor, a third low-pass-filter connected to the output of the ultra-low-power envelope/energy detector, and a fourth low-pass-filter connected to the output of the ultra-low-power envelope/energy detector.

According to still another exemplary embodiment there is provided a device and a method for a microphone including a transistor including at least one of a JFET and MOSFET transistor, an impedance network, where a first input terminal of the impedance network is connected to a gate terminal of the transistor, a source resistor, where a first terminal of the source resistor is connected to a source terminal of the transistor, and a second terminal of the source resistor is connected to a ground terminal, a bypass capacitor (CS) connected in parallel to the source resistor, a load resistor (RD), where a first terminal of the load resistor is connected to a drain terminal of the transistor, a charge pump generating a low voltage power supply VCC_LOW and an inverted voltage −VEE, where the low voltage is connected to a second terminal of the load resistor, and the inverted voltage −VEE is connected to a first power supply node of an op-amplifier, the op-amplifier, where a first input terminal of the op-amplifier is connected to a controlled reference voltage connected to first output terminal of a differential bi-directional low-pass-filter, where a first input terminal of the differential bi-directional low-pass-filter is connected to a second terminal of the load resistor, a second input terminal of the op-amplifier is connected to a second output terminal of a differential bi-directional low-pass-filter, where a second input terminal of the differential bi-directional low-pass-filter is connected to the first terminal of the load resistor, a first power supply of the op-amplifier terminal is connected to the inverted voltage, a second supply terminal of the op-amplifier is connected to the main supply voltage, and an output terminal of the op-amplifier is connected to a second terminal of the input impedance network through a second low pass filter, an input electrets capacitor source connected in parallel to the input impedance network, an ultra-low-power envelope/energy detector connected to drain terminal of the transistor via a coupling capacitor, a third low-pass-filter connected to the output of the ultra-low-power envelope/energy detector, and a fourth low-pass-filter connected to the output of the ultra-low-power envelope/energy detector.

Further according to another exemplary embodiment there is provided a device and a method for a microphone including a transistor including at least one of a JFET and MOSFET transistor, an impedance network, where a first input terminal of the impedance network is connected to a gate terminal of the transistor, a source resistor, where a first terminal of the source resistor is connected to a source terminal of the transistor, and a second terminal of the source resistor is connected to a ground terminal, a bypass capacitor (CS) connected in parallel to the source resistor, a load resistor (RD), where a first terminal of the load resistor is connected to a drain terminal of the transistor, a charge pump generating a low voltage power supply VCC_LOW and an inverted voltage −VEE, where the low voltage is connected to a second terminal of the load resistor, and the inverted voltage −VEE is connected to a first power supply node of an op-amplifier, an op-amplifier, where a first input terminal of the op-amplifier is connected to a controlled reference voltage connected to first output terminal of a differential bi-directional low-pass-filter, where a first input terminal of the differential bi-directional low-pass-filter is connected to a second terminal of the load resistor, a second input terminal of the op-amplifier is connected to a second output terminal of a differential bi-directional low-pass-filter, where a second input terminal of the differential bi-directional low-pass-filter is connected to the first terminal of the load resistor, a first power supply of the op-amplifier terminal is connected to the inverted voltage, a second supply terminal of the op-amplifier is connected to the main supply voltage, and an output terminal of the op-amplifier is connected to a second terminal of the input impedance network through a second low pass filter, and an input source including a MEMS capacitor, where a first terminal of the MEMS capacitor is connected to ground and a second terminal of the MEMS capacitor is connected to a first terminal of a MEMS bias network, a MEMS bias network connected with it second terminal to a bias voltage VBB, and the MEMS bias network, where a second terminal of the MEMS bias network is connected to a bias voltage VBB, and a coupling capacitor, where a first terminal of the coupling capacitor is connected to the second terminal of the MEMS capacitor, and with a second terminal of the coupling capacitor is connected to the gate terminal of the transistor.

Still further according to another exemplary embodiment the input impedance network includes a plurality of low-leakage diodes connected in series where a first diode cathode terminal is the first terminal of the input impedance network, a first diode anode terminal is connected to a second diode cathode terminal, and an anode terminal of diode N is the second terminal to the input impedance network.

Yet further according to another exemplary embodiment the input impedance network is includes a plurality of low-leakage diodes connected in series where a first diode anode terminal is the first terminal of the input impedance network, a first diode cathode terminal is connected to a second diode anode terminal, and a cathode terminal of diode N is the second terminal of the input impedance network.

Even further according to another exemplary embodiment the input impedance network includes of a parallel diode network including a first diode network including a plurality of diodes connected in series where a first diode cathode terminal is the first terminal of the input impedance network, a first diode anode terminal is connected to a second diode cathode terminal, and an anode terminal of diode N is the second terminal of the input impedance network, and a second diode network including a plurality of diodes connected in series where a first diode anode terminal is the first terminal of the input impedance network, a first diode cathode terminal is connected to a second diode anode terminal, and a cathode terminal of diode N is the second terminal to the input impedance network.

Additionally, according to another exemplary embodiment the input impedance network includes at least two series of two-terminal sub-networks where a first terminal of a first sub-network is the first terminal of the input impedance network, a second terminal of a last sub network is the second terminal of the input impedance network and where a sub-network includes a two low-leakage identical diodes connected in parallel in opposite polarity.

According to yet another exemplary embodiment the charge pump is a controlled charge pump.

According to still another exemplary embodiment the MEMS bias impedance network includes a plurality of low-leakage diodes connected in series, where a first diode cathode terminal is the first terminal of the MEMS bias impedance network, a first diode anode terminal is connected to a second diode cathode terminal, and an anode terminal of diode N is the second terminal to the MEMS bias impedance network.

Further according to another exemplary embodiment the MEMS bias impedance network includes plurality of low-leakage diodes connected in series, where a first diode anode terminal is the first terminal of the MEMS bias impedance network, a first diode cathode terminal is connected to a second diode anode terminal, and a cathode terminal of diode N is the second terminal to the MEMS bias impedance network.

Yet further according to yet another exemplary embodiment the MEMS bias impedance network includes a parallel diode network including a first and a second diode networks, the first diode network including a plurality of diodes connected in series, where a first diode cathode terminal is the first terminal of the MEMS bias impedance network, a first diode anode terminal is connected to a second diode cathode terminal, an anode terminal of diode N is the second terminal of the MEMS bias impedance network, and a second diode network including a plurality of diodes connected in series, where a first diode anode terminal is the first terminal of the MEMS bias impedance network, a first diode cathode terminal is connected to a second diode anode terminal, and a cathode terminal of diode N is the second terminal to the MEMS bias impedance network.

Still further according to yet another exemplary embodiment the MEMS bias impedance network includes of at least two series of two-terminal sub-networks where a first terminal of a first sub-network is the first terminal of the MEMS bias impedance network and a second terminal of a last sub network is the second terminal of the MEMS bias impedance network, where a sub network s includes two low-leakage identical diodes connected in parallel in opposite polarity.

Unless otherwise defined, all technical and scientific terms used herein have the same meaning as commonly understood by one of ordinary skill in the relevant art. The materials, methods, and examples provided herein are illustrative only and not intended to be limiting. Except to the extent necessary or inherent in the processes themselves, no particular order to steps or stages of methods and processes described in this disclosure, including the figures, is intended or implied. In many cases the order of process steps may vary without changing the purpose or effect of the methods described.

### BRIEF DESCRIPTION OF THE DRAWINGS

Various embodiments are described herein, by way of example only, with reference to the accompanying drawings. With specific reference now to the drawings in detail, it is stressed that the particulars shown are by way of example and for purposes of illustrative discussion of the preferred embodiments only, and are presented in order to provide what is believed to be the most useful and readily understood description of the principles and conceptual aspects of the embodiment. In this regard, no attempt is made to show structural details of the embodiments in more detail than is necessary for a fundamental understanding of the subject matter, the description taken with the drawings making apparent to those skilled in the art how the several forms and structures may be embodied in practice.

In the drawings:

FIG. 1 is a simplified block-diagram of a wakeup receiver implementation;

FIG. 2 is a simplified flow chart that describes the state machine of a transceiver;

FIG. 3 is a simplified electric schematic of a microphone element connected to a microphone buffer based on a JFET transistor;

FIG. 4 is a simplified electric schematic of an AC-equivalent circuit for noise/gain analysis of the circuit of FIG. 3;

FIG. 5 is a simplified electric schematic of a first exemplary circuit for eliminating RG in the buffer and decreasing noise due to leakage;

FIG. 6 is a simplified electric schematic of a second exemplary circuit for eliminating RG in the buffer and decreasing noise due to leakage;

FIG. 7 is a simplified electric schematic of a third exemplary circuit for eliminating RG in the buffer and decreasing noise due to leakage;

FIG. 8 is a simplified electric schematic of a fourth exemplary circuit for eliminating RG in the buffer and decreasing noise due to leakage;

FIG. 9 is a simplified electric schematic of an AC and noise equivalent circuit of FIG. 5;

FIG. 10 is a simplified electric schematic of an AC and noise equivalent circuit of FIG. 7;

FIG. 11 is a simplified schematic illustration of the distortion due to the diodes network;

FIG. 12 is a simplified illustration of an Electret Condenser Microphone (ECM) ultra-low-noise ultra-low-power microphone with a feedback from the source gate;

FIG. 13 is a simplified illustration of an Electret Condenser Microphone (ECM) ultra-low-noise ultra-low-power microphone with a feedback from the drain gate;

FIG. 14 is a simplified illustration of a Micro Electrical Mechanical System Microphone (MEMS) ultra-low-noise ultra-low-power microphone with a feedback from the source gate;

FIG. 15 is a simplified illustration of a Micro Electrical Mechanical System Microphone ultra-low-noise ultra-low-power microphone with a feedback from the drain gate;

FIG. 16 is a simplified illustration of an ECM Adaptive-SNR ultra-low-power ultra-low-noise with no current feedback;

FIG. 17 is a simplified illustration of a MEMS microphone Adaptive-SNR ultra-low-power ultra-low-noise—with no current feedback; and

FIG. 18 is a simplified electric schematic of a circuit generating ultra-low-noise biasing voltage VBB.

### DETAILED DESCRIPTION

The invention in embodiments thereof comprises systems and methods for an adaptive-SNR ultra-low-power and an ultra-low-noise microphone buffer. The principles and operation of the devices and methods according to the several exemplary embodiments presented herein may be better understood with reference to the following drawings and accompanying description.

Before explaining at least one embodiment in detail, it is to be understood that the embodiments are not limited in its application to the details of construction and the arrangement of the components set forth in the following description or illustrated in the drawings. Other embodiments may be practiced or carried out in various ways. Also, it is to be understood that the phraseology and terminology employed herein is for the purpose of description and should not be regarded as limiting.

In this document, an element of a drawing that is not described within the scope of the drawing and is labeled with a numeral that has been described in a previous drawing has the same use and description as in the previous drawings. Similarly, an element that is identified in the text by a numeral that does not appear in the drawing described by the text, has the same use and description as in the previous drawings where it was described.

The drawings in this document may not be to any scale. Different figures may use different scales and different scales can be used even within the same drawing, for example different scales for different views of the same object or different scales for the two adjacent objects.

The purpose of embodiments described below is to provide at least one system and/or method for ultra-low-power and an ultra-low-noise microphone, and/or a buffer circuit for a microphone, having adaptive signal-to-noise ratio (SNR). More particularly, but not exclusively, the microphone buffer may be used with battery-operated devices that have relatively long time operating in standby mode, and/or where immediate wakeup procedure is required. However, the systems and/or methods as described herein may have other embodiments in similar technologies of local area communication.

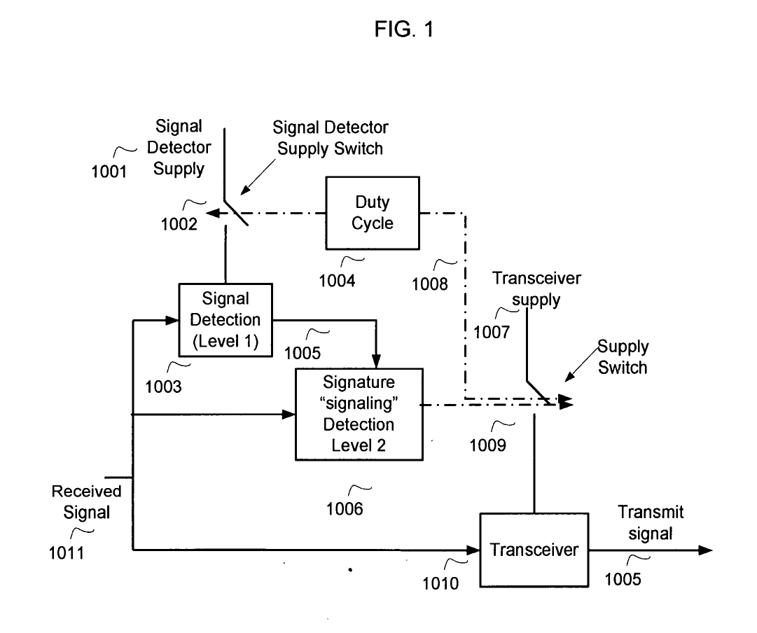

FIG. 1 is a simplified block-diagram of a wakeup receiver implementation, according to one exemplary embodiment.

As shown in FIG. 1, signal supply 1001 may be connected to level 1 signal detection module, 1003 for detection of signal presence 1011 in a particular bandwidth. If such signal exist, signal 1005 may turn on a signature and/or valid marker detection circuit 1006, which may consume more power. If the marker is valid, signal 1009 may switch on the transceiver power supply 1007, turning on the transceiver 1010. Alternatively, the wakeup receiver may periodically turn on the signal detection power supply using signal 1002. At that time the signal 1011 presence testing is done.

Implementing a periodically turn-on wakeup receiver, as shown and described with reference to FIG. 1, and common with Bluetooth low energy (BLE), may cause a delayed response of the transceiver, and consume a lot of power. For example, a BLE-based transceiver using a CR2032 battery may last only 8-14 months. The CR2032 battery may be too big for devices, such as glasses, buttons Used with pens or shirts), toothbrush, etc. Moreover, as the ISM band is highly populated, the number of false alarm may be too high, even if an envelope detector is implemented. It would not be easy to implement an effective bandwidth signal presence envelope detector.

Acoustic communication may enable a device to work for several years using a battery much smaller than the CR2032 (a 235 mah battery). Particularly by using the bandwidth between 14000 Hz and 20000 Hz, particularly if this 6000 Hz band is divided into sub-bands of, for example, 500 Hz each. Power consumed by acoustic communication may be 2000 times smaller compared with RF communication.

A signal transducer converting acoustic signal to electrical signal is, for example, a microphone. A common microphone may consume 17-500 μA. A highly efficient 17 μA microphone may consume a 1.47 mAh battery in about 90 hours. The 1.47 mAh battery is calculated for a battery size of 2.5 mm×2.5 mm×1 mm using the technology of the common CR2032 battery (having diameter of 20 mm and thickness of 3 mm).

Moreover, a common microphone may have signal-to-noise ratio (SNR) of about 68 dB, which limits the communication range. Therefore there is a need to have extremely low power wakeup receiver consuming 50-100 nWatt. Using a 3V battery, 50-100 nWatt is translated to 17 nA-33 nA, enabling 10 years of operation.

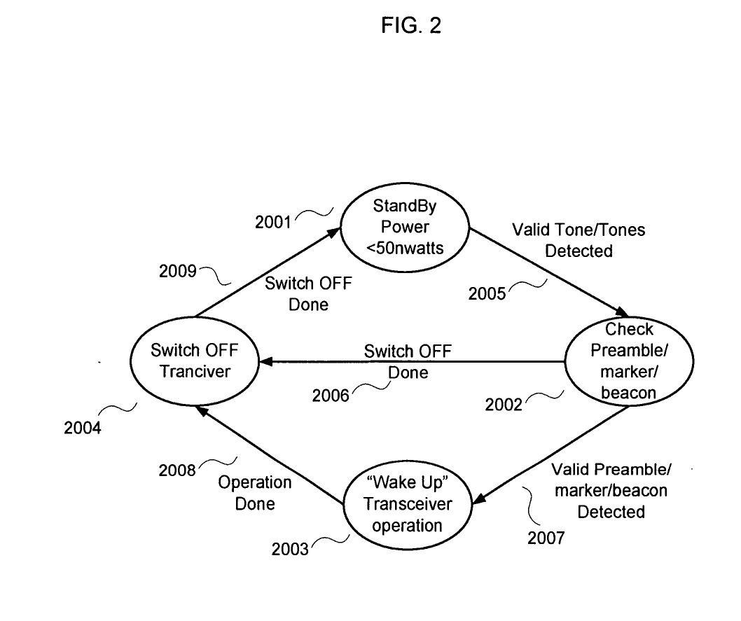

FIG. 2 is a simplified flow chart that describes the state machine of a transceiver, according to one exemplary embodiment.

As shown in FIG. 2, a first state 2001 an acoustic signal may be searched using ultra-low-power microphone, and ultra-low-power signal detection circuit, which may consume about 50 nWatt by a using low-frequency acoustic signal.

When the presence of an acoustic signal is detected 2005, the state machine transits to the check preamble/marker/beacon state 2002. If a false alarm 2006 is determined, the state machine transits to the switch-off state 2004, sending a switch-off signal 2009, and returns to the first state 2001. If the preamble/marker/beacon is valid 2007, the acoustic transceiver is turned on (wakeup), and the state machine transits to the wakeup state 2003, where the transceiver performs the required operation.

Acoustic-based transceivers, such as for IoT or IoE applications, may not be content-based transceivers, and may need to work ‘on-demand’ only. Therefore, most of the time such transceivers may be in standby state 2001 of FIG. 2.

Microphones are important as an input device for acoustic/audio waves for the increasing market of the smartphones/tablets/cellphones, requiring higher SNR for better acoustic echo canceling, and better audio quality. Such microphones also require extremely low-power to enable hands-free acoustic/audio activation, such as the android “OK Google”.

Moreover, for the IoT IoE devices microphones are important as an ‘antenna’, converting the acoustic communication signal to electrical signal. Such devices require many years of battery=based operation, and thus have to consume less than 50 nWatt. To enable a large communication range, such microphones require SNR better than 70 db. For example, enabling communication range up to 20-30 meters using 96 dB SPL signal.

Analysis of Prior Art Microphones SNR

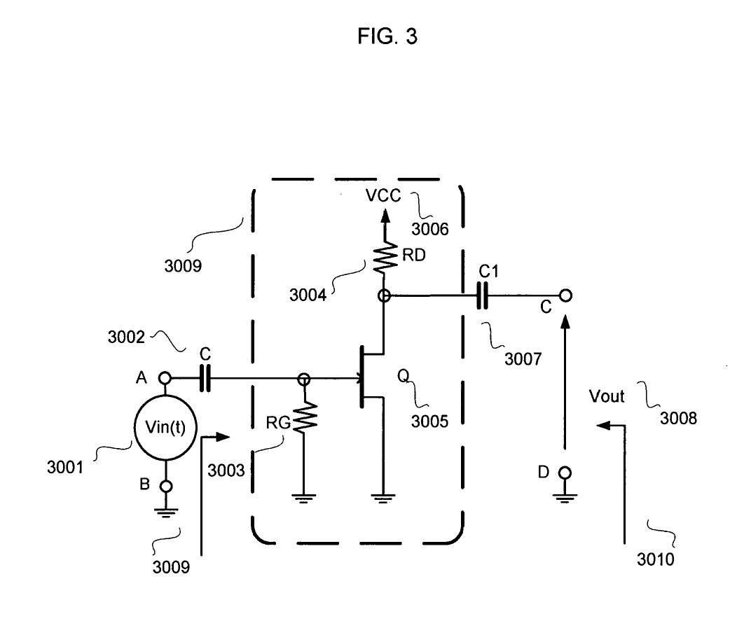

FIG. 3 is a simplified electric schematic of a microphone element connected to a microphone buffer based on a JFET transistor, according to one exemplary embodiment.

FIG. 3 describes a microphone element 3001, described here as a source of signal, usually coupled to the microphone buffer 3009 via a coupling capacitor 3002. The microphone buffer 3009 may include a gate bias resistor RG 3003, active element 3005 such as a JFET or a MOSFET transistor, a load resistor RD 3004 and a power supply VCC 3006. The output is coupled via a coupling capacitor.

The buffer 3009, may be used to transfer the signal from the acoustic transducer source 3001, showing a low capacitance at the input 3009, and low output impedance at the output 3010

Noise Gain Analysis of Prior Art Buffer

The following analysis may be suitable for any kind of microphone including, but not limited to, an Electret Condenser Microphone (ECM), and a Micro Electronic Mechanical Systems (MEMS) microphone.

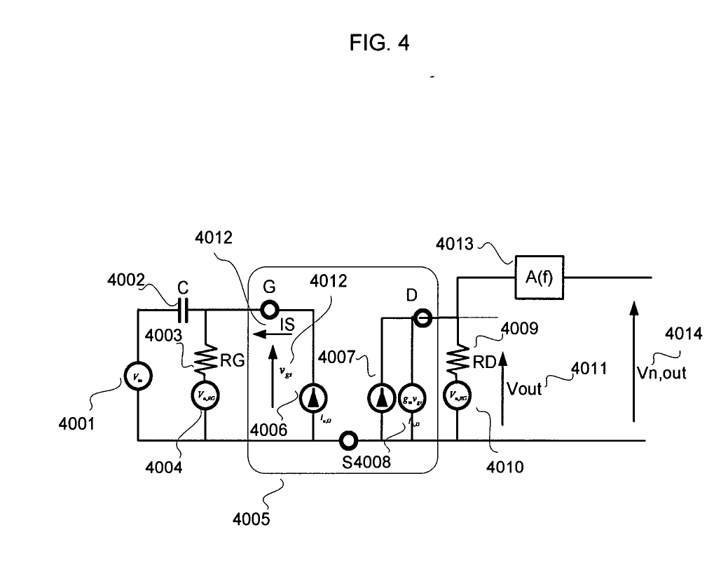

FIG. 4 is a simplified electric schematic of an AC-equivalent circuit for noise/gain analysis of the circuit of FIG. 3, according to one exemplary embodiment.

We assume that the active element 3005, JFET of FIG. 3 is in saturation mode i.e. where we get gain. As described by FIG. 4, there are a few noise sources for the circuit of FIG. 3

RG: Thermal noise from RG 4003, described by a serial voltage source 4004 and the noise is given by:

V_{n,RG}²=4KTR_{G}Δt, Eq. 1

where K is the Boltzmann constant and T is temperature in Kelvin degrees.

RD: Thermal noise from RD 4009, described by a serial voltage source 4004 and the noise is given by:

V_{n,RD}²=4KTR_{D}Δt Eq. 2

where K is the Boltzmann constant and T is temperature in Kelvin degrees.

Current Noise in the Drain Source.

Here we may neglect the 1/f noise, which appears at very low frequencies, the drain source current noise is given by:

i_{n,d}²=8/3KTgₘΔf Eq. 3

Current noise from the gate 4006 and is given by:

i_{n,d}²=2I_{S}qΔf Eq. 4

The noise in microphones may be calculated by considering an A-weighted filter 4013. A-weighted filter 4013 may simulate the human ear's frequency response, and may be given by Eq. 5.

$$A ( f ) = {10}^{( 2 / 20 )} \frac{{12200}^{2} {f}^{4}}{( {f}^{2} + {20.6}^{2} ) ( {f}^{2} + {12200}^{2} ) \sqrt{( {f}^{2} + {107.7}^{2} ) ( {f}^{2} + {739.7}^{2} )}} \qquad Eq . 5$$

Vout 4010 is given by:

$${v}_{out} = - {g}_{m} {v}_{in} ( \frac{j ω {R}_{G} C}{1 + j ω {R}_{G} C} ) {R}_{D} \qquad Eq . 6$$

Vn,out denotes the output of the filter 4014, and is given by:

$${v}_{n , out} ( f ) \sqrt{Δ f} - {g}_{m} \sqrt{4 {KTR}_{G} Δ f} ( \frac{1}{1 + j ω {R}_{G} C} ) {R}_{D} A ( f ) - {g}_{m} \sqrt{2 {I}_{S} q Δ f} ( \frac{{R}_{G}}{1 + j ω {R}_{G} C} ) {R}_{D} A ( f ) + {R}_{D} \sqrt{\frac{8}{3} {KTg}_{m} Δ f} A ( f ) + \sqrt{4 {KTR}_{D} Δ f} A ( f ) \qquad Eq . 7$$

where w=2πf assuming ωR_{G}C>>1n Eq. 6 and Eq. 7 becomes

$$\begin{matrix} {v}_{out} = - {g}_{m} {v}_{in} {R}_{D} & Eq . 8 \\ {v}_{n , out} ( f ) \sqrt{Δ f} \approx - {g}_{m} \sqrt{4 {KTR}_{G} Δ f} ( \frac{1}{j 2 π {fR}_{G} C} ) {R}_{D} A ( f ) - {g}_{m} \sqrt{2 {I}_{S} q Δ f} ( \frac{1}{j 2 π fC} ) {R}_{D} A ( f ) + {R}_{D} \sqrt{\frac{8}{3} {KTg}_{m} Δ f} A ( f ) + \sqrt{4 {KTR}_{D} Δ f} A ( f ) & Eq . 9\end{matrix}$$

To find the Root Mean Square noise, one should add the RMS noise elements in a df bandwidth (df denotes a small bandwidth) on f1=0 Hz to f2=20000 Hz or

$$\begin{matrix}\begin{matrix}{v}_{n , out}^{2} = & {\int }_{{f}_{1}}^{{f}_{2}} \vert {v}_{n , out} ( f ) {\vert}^{2} df \\ = & {g}_{m}^{2} 4 {KTR}_{D}^{2} ( \frac{1}{4 {π}^{2} {R}_{G} {C}^{2}} ) {\int }_{{f}_{1}}^{{f}_{2}} \frac{\vert A ( f ) {\vert}^{2}}{{f}^{2}} df + \\ & {g}_{m}^{2} 2 {I}_{S} {qR}_{D}^{2} ( \frac{1}{4 {π}^{2} {C}^{2}} ) {\int }_{{f}_{1}}^{{f}_{2}} \frac{\vert A ( f ) {\vert}^{2}}{{f}^{2}} df + \\ & \frac{8}{3} {KTg}_{m} {R}_{D}^{2} {\int }_{{f}_{1}}^{{f}_{2}} \vert A ( f ) {\vert}^{2} df + 4 {KTR}_{D} {\int }_{{f}_{1}}^{f2} \vert A ( f ) {\vert}^{2} df\end{matrix} \\ Or if & Eq . 10 \\ {ξ}_{1} = {\int }_{{f}_{1}}^{{f}_{2}} \frac{\vert A ( f ) {\vert}^{2}}{{f}^{2}} df , {ξ}_{2} = {\int }_{{f}_{1}}^{{f}_{2}} \vert A ( f ) {\vert}^{2} df then & Eq . 11 \\ \begin{matrix}{v}_{n , out}^{2} = & {\int }_{{f}_{1}}^{{f}_{2}} \vert {v}_{n , out} ( f ) {\vert}^{2} df = \\ = & {g}_{m}^{2} 4 {KTR}_{D}^{2} ( \frac{1}{4 {π}^{2} {R}_{G} {C}^{2}} ) {ξ}_{1} + \\ & {g}_{m}^{2} 2 {I}_{S} {qR}_{D}^{2} ( \frac{1}{4 {π}^{2} {C}^{2}} ) {ξ}_{1} + \\ & \frac{8}{3} {KTg}_{m} {R}_{D}^{2} {ξ}_{2} + 4 {KTR}_{D} Δ f {ξ}_{2}\end{matrix} & Eq . 12\end{matrix}$$

For f1=0 Hz, f2=20000 Hz one can show using Eq. 5 that

ξ₁=0.0026,ξ₂=12474 Eq. 13

As the gain is defined by G=gₘR_{D} then Eq. 12 may be written as

$$\begin{matrix}{v}_{n , out}^{2} = & {\int }_{{f}_{1}}^{{f}_{2}} \vert {v}_{n , out} ( f ) {\vert}^{2} df = \\ = & {G}^{2} 4 KT ( \frac{1}{4 {π}^{2} {R}_{G} {C}^{2}} ) {ξ}_{1} + {G}^{2} 2 {I}_{S} q ( \frac{1}{4 {π}^{2} {C}^{2}} ) {ξ}_{1} + \\ & G \frac{8}{3} {KTR}_{D} {ξ}_{2} + 4 {KTR}_{D} {ξ}_{2}\end{matrix} \qquad Eq . 14$$

and the noise equivalent at the input is

$$\begin{matrix}{v}_{n , in}^{2} = & \frac{{v}_{n , out}^{2}}{{G}^{2}} = \frac{1}{{G}^{2}} {\int }_{{f}_{1}}^{{f}_{21}} \vert {v}_{n , out} ( f ) {\vert}^{2} df = \\ = & 4 KT ( \frac{1}{4 {π}^{2} {R}_{G} {C}^{2}} ) {ξ}_{1} + 2 {I}_{S} q ( \frac{1}{4 {π}^{2} {C}^{2}} ) {ξ}_{1} + \\ & \frac{8}{3 G} {KTR}_{D} {ξ}_{2} + \frac{4 {KTR}_{D} {ξ}_{2}}{{G}^{2}}\end{matrix} \qquad Eq . 15$$

Analysis of Noise Terms

For

$$4 KT ( \frac{1}{4 {π}^{2} {R}_{G} {C}^{2}} ) {ξ}_{1}$$

it is clear that having large C and large RG will decrease the noise, however for ECM or MEMS microphones C=5 pf-10 pF In This kind of microphones SNR is limited in the range of 58 dB-67 dB this may be due to the small size RG, which is usually in the range of 25 MOhm-100 MOhm for a common microphone (we assume RG=100M Ohm.)

$$\sqrt{4 KT ( \frac{1}{4 {π}^{2} {R}_{G} {C}^{2}} ) {ξ}_{1}} = 10.4 uv \qquad Eq . 16 A$$

Increasing RG to 1G will give a noise of about 3 uv for RG=1G and microphone sensitivity of −38 dBv=12.6 mV the reflected (not taking into account other terms) SNR from this noise is

$$20 {log}_{10} ( \frac{12.6 mv \text{/} \sqrt{2}}{3 uv} ) = 69.45 dB .$$

Table 1 and table 1A summarizes the A-weighted noise and SNR for various C & RG values.

TABLE 1
Equivalent A-weighted noise at the input
induced by Rg for various Rg and C values

| | | C | | | | |
|---|---|---|---|---|---|---|
| Rg | | 5 pF | 10 pF | 30 pF | 56 pF | 100 pF |
| 25 | MOhm | 41.77 μV | 20.89 μV | 6.96 μV | 37.3 μV | 2.09 μV |
| 100 | MOhm | 20.89 μV | 10.44 μV | 3.48 μV | 18.6 μV | 1.04 μV |
| 1 | GOhm | 6.6 μV | 3.3 μV | 1.1 μV | 5.9 μV | 0.33 μV |
| 10 | GOhm | 2.09 μV | 1.04 μV | 0.35 μV | 1.9 μV | 0.1 μV |

TABLE 1A
SNR with A weighted noise at the input induced
by Rg for various Rg and C values.

| | C | | | | |
|---|---|---|---|---|---|
| Rg | 5 pf | 10 pf | 30 pf | 56 pf | 100 pf |
| 25 | 46.6[dB] | 52.6[dB] | 62.16[dB] | 67.6[dB] | 72.6[dB] |
| MOhm | | | | | |
| 100 | 52.6[dB] | 58.6[dB] | 68.16[dB] | 73.6[dB] | 78.6[dB] |
| MOhm | | | | | |
| 1 | 62.6[dB] | 68.6[dB] | 78.16[dB] | 83.6[dB] | 88.6[dB] |
| GOhm | | | | | |
| 10 | 72.6[dB] | 78.6[dB] | 88.16[dB] | 93.6[dB] | 98.6[dB] |
| GOhm | | | | | |

For

$$2 {I}_{S} q ( \frac{1}{4 {π}^{2} {C}^{2}} ) {ξ}_{1}$$

where Is, 4012 is the leakage current, it is clear that having smaller leakage current will decrease the noise from the JFET hate leakage current, C again is 5 pf-10 pf, for Is=1000 pa one get:

$$\sqrt{2 {I}_{S} q ( \frac{1}{4 {π}^{2} {C}^{2}} ) {ξ}_{1}} = 14.5 uv \qquad Eq . 16 B$$

and for Is=1 pA one gets 0.46 μV and for Is=0.2 pA one gets 0.21 μV for microphone with −38 dBv=12.6 mV sensitivity and IS=1000 pA, 1 pA and 0.2 pA.

The reflected SNR is:

$$Is = 1000 pa \to 20 {log}_{10} ( \frac{12.6 mv \text{/} \sqrt{2}}{14.5 uv} ) = 55 dB$$

$$Is = 1 pa \to 20 {log}_{10} ( \frac{12.6 mv \text{/} \sqrt{2}}{0.46 uv} ) = 85 dB$$

$$Is = 0.2 pa \to 20 {log}_{10} ( \frac{12.6 mv \text{/} \sqrt{2}}{0.21 uv} ) = 92.6 dB$$

Table 2 and table 2A summarizes the input equivalent a weighted noise and the associated SNR for −38 dBv sensitivity:

TABLE 2
Equivalent A weighted noise at the input induced by JFET
leakage noise current for different leakage and C values.

| | | C | | | | | | |
|---|---|---|---|---|---|---|---|---|
| Is | | 5 pf | | 10 pf | | 30 pf | 56 pf | 100 pf |
| 1000 | pA | 29.03 | μV | 14.52 | μV | 4.84 μV | 2.59 μV | 1.45 μV |
| 100 | pA | 9.18 | μV | 4.59 | μV | 1.53 μV | 0.82 μV | 0.46 μV |
| 2 | pA | 1.3 | μV | 0.65 | μV | 0.22 μV | 0.12 μV | 0.06 μV |
| 1 | pA | 0.92 | μV | 0.46 | μV | 0.15 μV | 0.08 μV | 0.05 μV |

TABLE 2A
SNR with A weighted noise at the input induced by JFET leakage
noise current for different leakage and C values

| | C | | | | |
|---|---|---|---|---|---|
| Rg | 5 pf | 10 pf | 30 pf | 56 pf | 100 pf |
| 1000 | 49.74[dB] | 55.76[dB] | 65.30[dB] | 70.72[dB] | 75.76[dB] |
| pA | | | | | |
| 100 | 59.74[dB] | 65.76[dB] | 75.30[dB] | 80.72[dB] | 85.76[dB] |
| pA | | | | | |
| 2 | 76.3[dB] | 82.75[dB] | 92.30[dB] | 97.71[dB] | 102.75[dB] |
| pA | | | | | |
| 1 | 79.74[dB] | 85.76[dB] | 95.30[dB] | 100.72[dB] | 105.76[dB] |
| pA | | | | | |

For other two terms

$$\frac{8}{3 G} {KTR}_{D} {ξ}_{2} and \frac{4 {KTR}_{D} {ξ}_{2}}{{G}^{2}}$$

we assume a JFET with IDSS=0.5 mA, Vp=−1V, and RD=1000 Ohm, which are typical values (here we neglected the Cgs that gives attenuation at the input by 2 and therefore usually one selects RD=2000 Ohm.

Using these values it is clear that

$${g}_{m} = \frac{2}{{V}_{P}} \sqrt{{I}_{D} {I}_{DSS}} = \frac{2 {I}_{DSS}}{{V}_{P}} \{ at {V}_{GS} = 0 \} = 0.001 {( ohm )}^{- 1} and G = {g}_{m} {R}_{D} = 1$$

For

$$\frac{8}{3 G} {KTR}_{D} {ξ}_{2}$$

it is clear that smaller RD will decrease the noise as well as larger G. This is possible by increasing the current, for typical ECM or MEMS microphones.

$$\sqrt{\frac{8}{3 G} {KTR}_{D} {ξ}_{2}} = 0.37 uv \qquad Eq . 16 C$$

And for −38 dBv=12.6 mV microphone the reflected SNR here is

$$20 {log}_{10} ( \frac{12.6 mv / \sqrt{2}}{0.37 uv} ) = 87.6 dB .$$

This number may be easily increased by lowering RD, by using enlarged IDSS JFET, for example by using JFET with IDSS=5 ma we can use RD=100 ohm and in this case the SNR will be

$$20 {log}_{10} ( \frac{12.6 mv / \sqrt{2}}{0.123 uv} ) = 97.2 dB$$

For

$$\frac{4 {KTR}_{D} {ξ}_{2}}{{G}^{2}}$$

it is clear that decreasing RD and increasing G will decrease this term, for typical ECM and/or MEMS microphones we have:

$$\sqrt{\frac{4 {KTR}_{D} {ξ}_{2}}{{G}^{2}}} = 0.45 uv \qquad Eq . 16 D$$

Which for −38 dBv microphone sensitivity reflects an SNR of

$$20 {log}_{10} ( \frac{12.6 mv / \sqrt{2}}{0.45 uv} ) = 85.9 dB$$

as before by decreasing RD by 10 by using JFET with IDSS=5 ma the reflected SNR would become

$$20 {log}_{10} ( \frac{12.6 mv / \sqrt{2}}{0.45 uv} ) = 96 dB$$

### CONCLUSIONS

As one can see the limiting factor for the SNR is the RG, then the leakage current while the last two term are easily decreased by using JFET with larger IDSS and hence smaller RD. On the other hand C may be increased by putting a parallel to gate and source a second capacitor that may decrease the noise coming from RG 4003 and the noise due to the leakage IS 4012. The capacitor may cause attenuation that may be compensated by increasing the gm trans-conductance of the JFET 4005, by increasing the drain current.

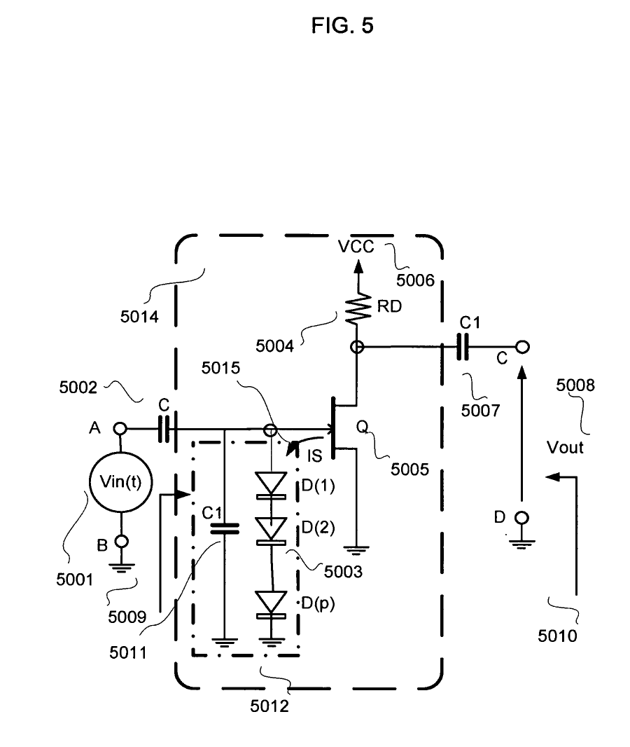

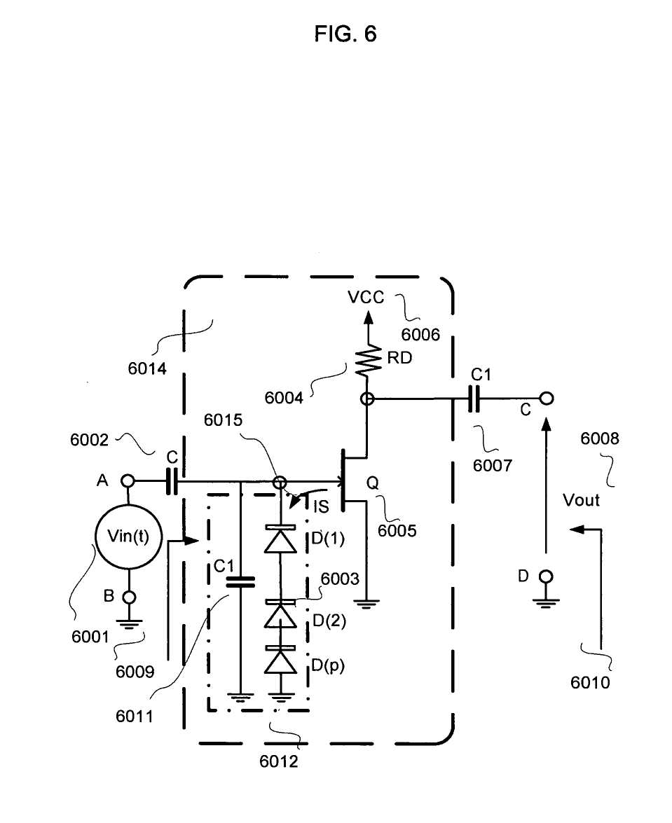

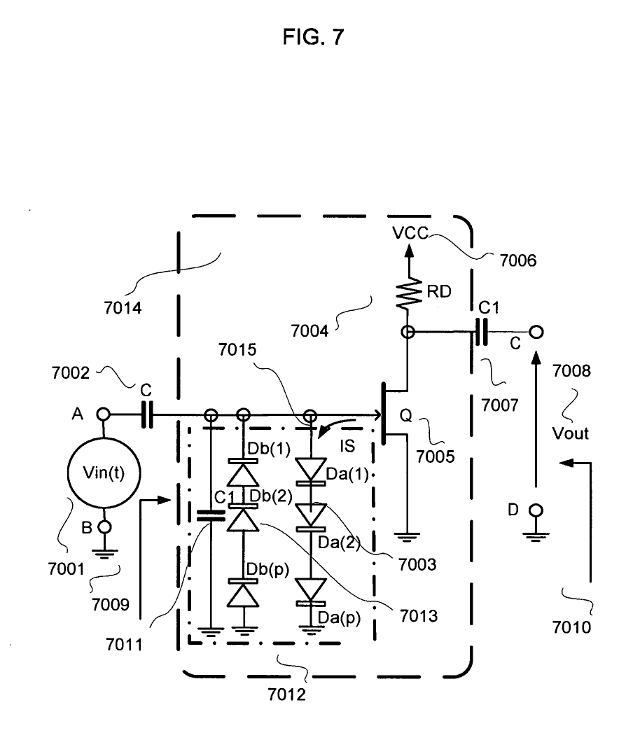

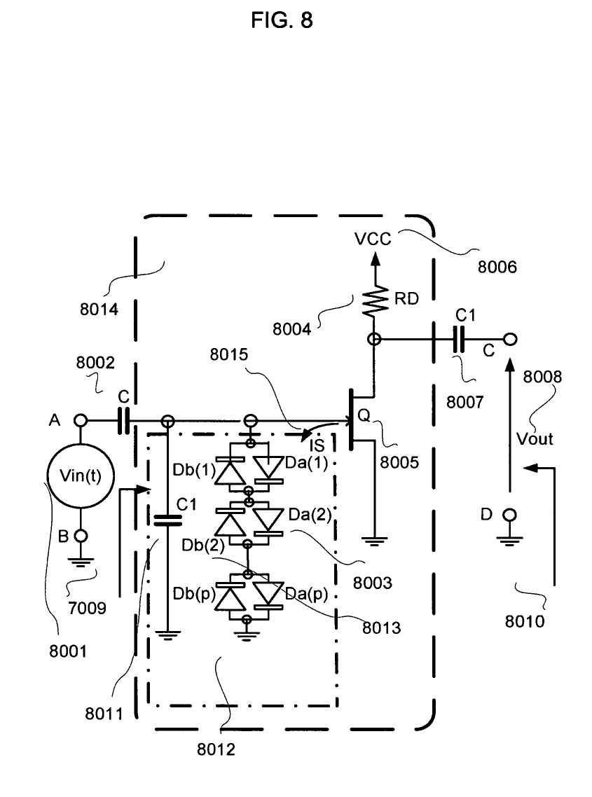

FIG. 5, FIG. 6, FIG. 7 and FIG. 8 describe the solution for the RG problem with a possible parallel capacitor C1.

FIG. 5 is a simplified electric schematic of a first exemplary circuit for eliminating RG in the buffer and decreasing noise due to leakage, according to one exemplary embodiment.

FIG. 6 is a simplified electric schematic of a second exemplary circuit for eliminating RG in the buffer and decreasing noise due to leakage, according to one exemplary embodiment.

FIG. 7 is a simplified electric schematic of a third exemplary circuit for eliminating RG in the buffer and decreasing noise due to leakage, according to one exemplary embodiment.

FIG. 8 is a simplified electric schematic of a fourth exemplary circuit for eliminating RG in the buffer and decreasing noise due to leakage, according to one exemplary embodiment.

Circuits of FIG. 5, FIG. 6, FIG. 7 and FIG. 8 are based on a network of diodes 6012, 7012, 8012 and 9012 and capacitor C1 5011, 6011, 7011 and 8011.

Analysis of Serial Diodes Network Connection

Reference is now made to FIG. 5. FIG. 5A describes in details the diodes 5003 with the capacitor C1 5011.

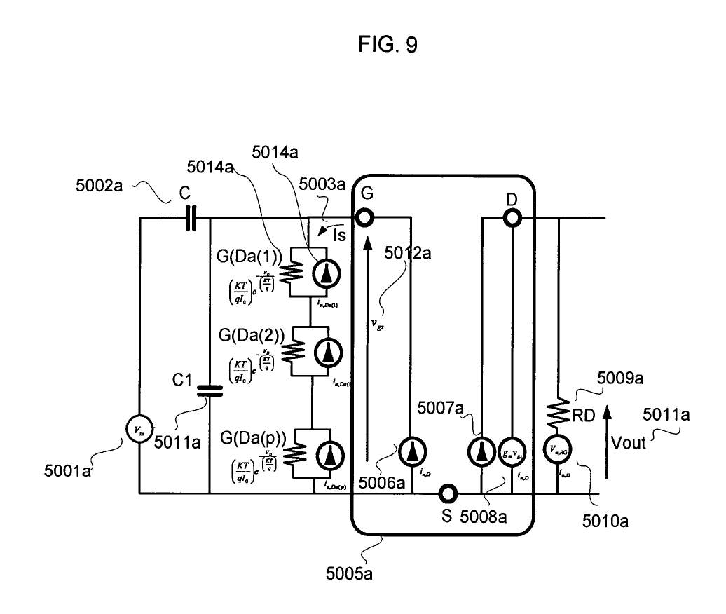

FIG. 9 is a simplified electric schematic of an AC and noise equivalent circuit of FIG. 5, according to one exemplary embodiment.

The noise of each diode Da(1), Da(2) . . . Da(p) 5003 of FIG. 5 is given by:

i_{n,Da(k)}²=(2I_{S}+I₀)qΔf Eq. 17

Diode Small Signal Resistance

The small signal diode resistance is given by:

$${[ \frac{{I}_{0}}{( \frac{KT}{q} )} {e}^{\frac{{V}_{D}}{( \frac{KT}{q} )}} ]}^{- 1} = ( \frac{KT}{{qI}_{0}} ) {e}^{- \frac{{V}_{D}}{( \frac{KT}{q} )}} \approx ( \frac{KT}{{qI}_{0}} ) {( \frac{KT}{{qV}_{D}} )}_{Forsmall {V}_{D} {V}_{D} << \frac{KT}{q}}$$

If a diode with I₀≈I_{S} is selected then

$${V}_{D ( DC )} = \frac{KT}{q} ln ( 2 ) = 0.69 \frac{KT}{q} = 17.3 {mv}_{at 25 deg}$$

in this case the diode small signal resistance is given by

$$( \frac{KT}{2 {qI}_{S}} ) .$$

It may be important to select a diode that may not have higher leakage current than the Is. This may help reducing diode noise. And, if I₀≈I_{S}, then the DC voltage on the diode may be small, such that connecting 10-20 diodes in series may not create a high voltage drop on the diodes.

Diode Current Noise Calculation and Reduction

The reason for connecting diodes in series is to reduce the distortion resulting from the diodes. First we show that connecting a diodes in series reduces the total diode noise.

One can transform the diodes 5003, circuit of FIG. 5A using the Thevenin theorem and get the following total current with the following total resistance.

$${i}_{n , diodes} = \frac{\sqrt{( 2 {I}_{S} + {I}_{0} ) q Δ {f ( \frac{KT}{2 {qI}_{s}} )}^{2} + ( 2 {I}_{S} + {I}_{0} ) q Δ {f ( \frac{KT}{2 {qI}_{s}} )}^{2} + … + ( 2 {I}_{S} + {I}_{0} ) q Δ {f ( \frac{KT}{2 {qI}_{s}} )}^{2}}}{p ( \frac{KT}{2 {qI}_{s}} )} == \frac{\sqrt{( 2 {I}_{S} + {I}_{0} ) q Δ f}}{\sqrt{p}} \qquad Eq . 18$$

And the total resistance is

$$p ( \frac{KT}{2 {qI}_{s}} ) ,$$

which does not give any thermal noise, as it is just the slope of the diode current, having C1.

The total current noise is the square sum of the diode noise and the gate leakage noise 5014a, and is given by:

$${i}_{n , diodes + jfet}^{2} = \frac{( 2 {I}_{S} + {I}_{0} ) q Δ f}{p} + 2 {I}_{S} q Δ f \approx 2 {I}_{S} q Δ f for p \geq 10 \qquad Eq . 19$$

We can conclude that Eq. 15 now will take the form:

$${v}_{n , in}^{2} = \frac{{v}_{n , out}^{2}}{{G}^{2}} = \frac{1}{{G}^{2}} {\int }_{{f}_{1}}^{{f}_{2}} {\vert {v}_{n , out} ( f ) \vert}^{2} df = 2 {I}_{S} q ( \frac{1}{4 {{π}^{2} ( C + {C}_{1} )}^{2}} ) {ξ}_{1} + \frac{8}{3 G} {KTR}_{D} {{ξ}_{2} [ \frac{( C + {C}_{1} )}{C} ]}^{2} ++ {\frac{4 {KTR}_{D} {ξ}_{2}}{{G}^{2}} [ \frac{( C + {C}_{1} )}{C} ]}^{2} \qquad Eq . 20$$

One can see from equation 20 that C1 helps reducing the current noise from the PN junction of the JFET and the diode noise. Also, connecting diodes in series helps with reducing the diode current noise. The noise from the JFET current at the output 5007a and the noise from RD at the output 5010a is reflected to the input by a factor greater than 1

$${[ \frac{( C + {C}_{1} )}{C} ]}^{2} .$$

For 1 pA leakage current we had

$$Is = 1 pa -> 20 {log}_{10} ( \frac{12.6 mv / \sqrt{2}}{0.46 uv} ) = 85 dB .$$

It is possible to increase this term by 10 dB by adding C1=2 C. This requires that G compensates the

$${[ \frac{( C + {C}_{1} )}{C} ]}^{2} .$$

Therefore it requires that G=10, still having Rd=100 ohm, which requires gm=0.1, or Id=100 ma. This is possible when using JFET with IDSS=100 mA.

Distortion Analysis

The equation of a diode is given by:

$$\begin{matrix}\begin{matrix}{I}_{D} = {I}_{0} ( {e}^{\frac{{V}_{D}}{( \frac{KT}{q} )}} - 1 ) \\ = {I}_{0} ( ( \frac{{V}_{D}}{{V}_{T}} ) + \frac{1}{2 !} {( \frac{{V}_{D}}{{V}_{T}} )}^{2} + \frac{1}{3 !} {( \frac{{V}_{D}}{{V}_{T}} )}^{3} + \frac{1}{4 !} {( \frac{{V}_{D}}{{V}_{T} } )}^{4} … ) \\ = {I}_{0} ( ( x ) + \frac{1}{2 !} {( x )}^{2} + \frac{1}{3 !} {( x )}^{3} + \frac{1}{4 !} {( x )}^{4} … )\end{matrix} & Eq . 21 \\ where {V}_{T} = \frac{KT}{q} and x = \frac{{V}_{D}}{{V}_{T}} & \end{matrix}$$

It is clear that for 1 pA-10 pA the impedance of a diode is about 25 mV/(2*1e-12)=12.5 GOhm, which means that all Von will be developed if we have C=10 pF 5002a at even low frequencies like 100 Hz. Also, it is known that the voltage on a microphone acoustic element is about its sensitivity, which is about 12 mV. This means that 12 mV/25 mc=x=0.5 will generate relatively high distortion. By adding several diodes the Vin voltage may be divided over all the diodes, and hence by having for example p=25 we have x=0.5 mv/25 mv= 1/50. This means that the next that the distortion will come from

$$\frac{1}{2 !} {( \frac{{V}_{D}}{{V}_{T}} )}^{2} ,$$

as

$$\frac{1}{2 !} {( \frac{{V}_{D}}{{V}_{T}} )}^{2} = \frac{1}{2 !} {( \frac{{V}_{D} ( d c ) + Vin / P}{{V}_{T}} )}^{2} = \frac{1}{2 !} ( \frac{{V}_{D} ( d c )}{{V}_{T}} + 2 \frac{{V}_{D} ( d c )}{{V}_{T}} \frac{Vin}{P} + {( \frac{Vin / P}{{V}_{T}} )}^{2} ) .$$

Therefore showing that the distortion current is

$${I}_{0} \frac{1}{2 !} {( \frac{Vin / P}{{V}_{T}} )}^{2}$$

for I0=10 pA, C=10 pf and f=100 Hz, p=1.

The maximum sensitivity of the distortion voltage may therefore be:

Analysis of serial diodes network connection of FIGS. 7 and 8.

Reference is now made to FIG. 7 and FIG. 7A describes in details the diodes 7003, 7013 with the capacitor C1 7011.

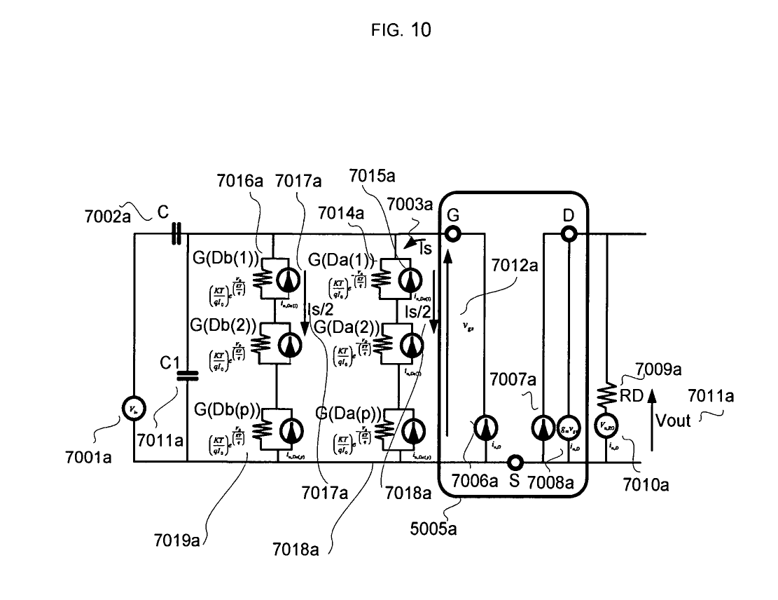

FIG. 10 is a simplified electric schematic of an AC and noise equivalent circuit of FIG. 7, according to one exemplary embodiment.

As shown in FIG. 7, a dual branch network of p diodes per each network is connected between the gate (input) and ground, typically including a first network 7003 and a second network 7013. If Vgs=V then each diode of the first network 7003 gets a voltage of V/p while each diode of the second network gets −V/p.

As V is very small, the current flowing on the first network is equal to about

$${I}_{0} ( ( V / p ) + \frac{1}{2 !} {( V / p )}^{2} + \frac{1}{3 !} {( V / p )}^{3} + \frac{1}{4 !} {( V / p )}^{4} … )$$

and for the second network 7013

$$- {I}_{0} ( ( V / p ) - \frac{1}{2 !} {( V / p )}^{2} + \frac{1}{3 !} {( V / p )}^{3} - \frac{1}{4 !} {( V / p )}^{4} … )$$

with V/p is the voltage across Da(1), Da(2) . . . Da(p) the first diode branch 7015a and −V/p is the voltage across Db(1), Db(2) . . . Db(p) the second diode branch 7017a.

Part of the JFET leakage is 7003a may flow through the first branch 7015a and another part may flow through the second branch 7017a

The noise of each diode Da(1), Da(2) . . . Da(p) 7003 of FIG. 7 is given by:

i_{n,Da(k)}²(2αI_{S}+I₀)qΔf Eq. 22

where αI_{S} is the current flowing into the first diode branch from the JFET leakage.

The reason for connecting diodes in series is reducing the distortion. The input voltage V may be divided by P for each diode as well as reducing the noise resulting from the diode noise current. First we show that connecting diodes in series reduces the total diode noise.

One can transform the diodes of branch 7003 of the circuit of FIG. 7A using the Thevenin theorem and get the following total current with the following total resistance

$${i}_{n , diodes} = \frac{\sqrt{\begin{matrix}( 2 α {I}_{S} + {I}_{0} ) q Δ {f ( \frac{2 KT}{{qI}_{0}} {e}^{- \frac{{V}_{D}}{( \frac{KT}{q} )}} )}^{2} + \\ \begin{matrix}( 2 α {I}_{S} + {I}_{0} ) q Δ {f ( \frac{2 KT}{{qI}_{0}} {e}^{- \frac{{V}_{D}}{( \frac{KT}{q} )}} )}^{2} + … + \\ ( 2 α {I}_{S} + {I}_{0} ) q Δ {f ( \frac{2 KT}{{qI}_{0}} {e}^{- \frac{{V}_{D}}{( \frac{KT}{q} )}} )}^{2}\end{matrix}\end{matrix}}}{p ( \frac{2 KT}{{qI}_{0}} {e}^{- \frac{{V}_{D}}{( \frac{KT}{q} )}} )} == \frac{\sqrt{( 2 α {I}_{S} + {I}_{0} ) q Δ f}}{\sqrt{p}} \qquad Eq . 22$$

And the total resistance is

$$p ( \frac{2 KT}{{qI}_{0}} {e}^{- \frac{{V}_{D}}{( \frac{KT}{q} )}} ) ,$$

which does not give any thermal noise as it is just the slope of the diode current, having C1. The same applies to the second diode network 7013.

The total current noise is the square sum of the first diode branch current noise the second diode branch current noise and the gate leakage noise 5014a and is given by:

$${i}_{n , diodes + jfet}^{2} = \frac{( 2 α {I}_{S} + {I}_{0} ) q Δ f}{p} + \frac{( 2 ( 1 - α ) {I}_{S} + {I}_{0} ) q Δ f}{p} + 2 {I}_{S} q Δ f == \frac{( 2 {I}_{S} + 2 {I}_{0} ) q Δ f}{p} + 2 {I}_{S} q Δ f \approx 2 {I}_{S} q Δ f for p \geq 10 \qquad Eq . 23$$

We can conclude that Eq. 15 now will take the form

$${v}_{n , i n}^{2} = \frac{{v}_{n , out}^{2}}{{G}^{2}} = \frac{1}{{G}^{2}} {\int }_{{f}_{1}}^{{f}_{2}} {\vert {v}_{n , out} ( f ) \vert}^{2} df = 2 {I}_{S} q ( \frac{1}{4 {{π}^{2} ( C + {C}_{1} )}^{2}} ) {ξ}_{1} + \frac{8}{3 G} {KTR}_{D} {{ξ}_{2} [ \frac{( C + {C}_{1} )}{C} ]}^{2} + {\frac{4 {KTR}_{D} {ξ}_{2}}{{G}^{2}} [ \frac{( C + {C}_{1} )}{C} ]}^{2} \qquad Eq . 24$$

One can see from equation 24 that C1 helps reducing the current noise from the PN junction of the JFET and the diode noise. Connecting diodes in series also helps reducing the diode current noise. The noise from the JFET current at the output 5007a and the noise from RD at the output 5010a may be reflected to the input by a factor greater than 1

$${[ \frac{( C + {C}_{1} )}{C} ]}^{2} .$$

For 1 pA leakage current we had

$$Is = 1 pa -> 20 {log}_{10} ( \frac{12.6 mv / \sqrt{2}}{0.46 uv} ) = 85 dB .$$

It is therefore possible to increase this term by 10 dB by adding C1=2C. This requires that G may compensate the

$${[ \frac{( C + {C}_{1} )}{C} ]}^{2} .$$

requiring that G=10. Having Rd=100 ohm requires gm=0.1, or Id=100 ma, which is possible using JFET with IDSS=100 mA.

Distortion Analysis

The equation of a diode is given by:

$$\begin{matrix}\begin{matrix}{I}_{D} = {I}_{0} ( {e}^{\frac{{V}_{D}}{( \frac{KT}{q} )}} - 1 ) = \\ = {I}_{0} ( ( \frac{{V}_{D}}{{V}_{T}} ) + \frac{1}{2 !} {( \frac{{V}_{D}}{{V}_{T}} )}^{2} + \frac{1}{3 !} {( \frac{{V}_{D}}{{V}_{T}} )}^{3} + \frac{1}{4 !} {( \frac{{V}_{D}}{{V}_{T}} )}^{4} … ) = \\ = {I}_{0} ( ( x ) + \frac{1}{2 !} {( x )}^{2} + \frac{1}{3 !} {( x )}^{3} + \frac{1}{4 !} {( x )}^{4} … )\end{matrix} & Eq . 25 \\ where {V}_{T} = \frac{KT}{q} and x = \frac{{V}_{D}}{{V}_{T}} & \end{matrix}$$

At DC the first diode branch 7003 may force a positive voltage across the diode branch. This may appear to the second diode branch 7013 as a negative voltage. To find this voltage one can write.

$${I}_{s} = {I}_{0} ( {e}^{\frac{{V}_{D}}{( \frac{KT}{q} )}} - 1 ) - {I}_{0} ( {e}^{- \frac{{V}_{D}}{( \frac{KT}{q} )}} - 1 ) mark x = {e}^{\frac{{V}_{D}}{( \frac{KT}{q} )}} solve \frac{{I}_{s}}{{I}_{0}} = x - 1 - \frac{1}{x} + 1 if \frac{{I}_{s}}{{I}_{0}} = 1 \qquad Eq . 26$$

Meaning that the diode may have leakage in the same order as JFET. This will result at 25 degrees with x=1.618 and v_{D}=12 mv.

As each diode in the first branch 7003 gets V/p and on the second branch 7013 gets −V/p and the current for both branches is the subtraction of the currents between branch 7003 and 7013.

Then the diode on the first branch 7003 would have 12 mV+V/p and on the second branch −12 mV−V/p, where, as explained above, the 12 mV results from the leakage Is 7013 flowing from the transistor Q 7005 to the diodes on branch 7003.

Eq. 27 gives the current difference between the branches 7003, 7013

$$\begin{matrix}{I}_{on\_diode \_branches \_ 7003 \_ 7013} == {I}_{0} ( ( x ) + \frac{1}{2 !} {( x )}^{2} + \frac{1}{3 !} {( x )}^{3} + \frac{1}{4 !} {( x )}^{4} … ) - {I}_{0} ( ( - x ) + \frac{1}{2 !} {( x )}^{2} + \frac{1}{3 !} {( - x )}^{3} + \frac{1}{4 !} {( x )}^{4} … ) & Eq . 27 \\ where {V}_{T} = \frac{KT}{q} and & \\ x = \frac{V / p + 12 mv}{{V}_{T}} = 2 {I}_{0} ( ( x ) + \frac{1}{3 !} {( x )}^{3} … ) == 2 {I}_{0} ( ( \frac{V / p}{{V}_{T}} ) + \frac{1}{3 !} {( \frac{12 mv}{{V}_{T}} )}^{3} ( 1 + 3 {( \frac{V / p}{12 mv} )}^{2} + 3 ( \frac{V / p}{12 mv} ) + {( \frac{V / p}{12 mv} )}^{3} ) … ) & \end{matrix}$$

If we have C=10 pf 7002a at even low frequencies like 100 Hz, It is clear that for 1 pa-10 pa the impedance of a diode is about 25 mv/(2*1e-12)=12.5 Gohm, which means that all Vin will be developed on the input.

The distortion voltage at the input would come from the voltage drop on C and from the distortion elements described by Eq. 27.

For Very small V/p (Assuming microphone acoustic element is about its sensitivity which is about 12 mV this means that 12 mV/10=1.2 mV).

The term

$$3 {( \frac{V / p}{12 mv} )}^{2} \frac{1}{3 !} {( \frac{12 mv}{{V}_{T}} )}^{3} = 2 {I}_{0} \frac{1}{2} {( \frac{V / p}{1} )}^{2} ( \frac{12 mv}{{V}_{T}} ) \approx {{I}_{S} ( \frac{V / p}{1} )}^{2} ( \frac{12 mv}{{V}_{T}} )$$

generates the distortion.

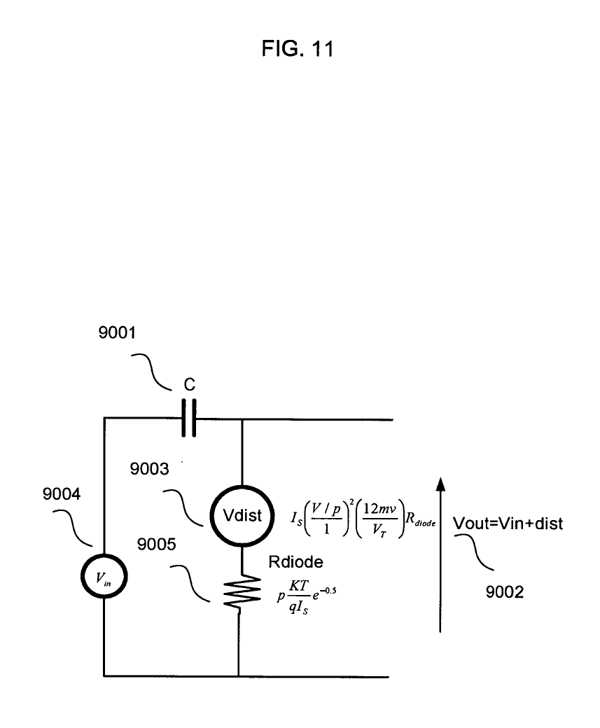

FIG. 11 is a simplified schematic illustration of the distortion due to the diodes network, according to one exemplary embodiment.

One can show that the distortion is given by

$${{I}_{S} ( \frac{{V}_{i n} / p}{1} )}^{2} ( \frac{12 mv}{{V}_{T}} ) ( \frac{1}{jwc} ) \qquad Eq . 28$$

and therefore in dB we have

$$Distotion [ dB ] = 20 log 10 [ \frac{{{I}_{S} ( \frac{{V}_{i n} / p}{1} )}^{2} ( \frac{12 mv}{{V}_{T}} ) ( \frac{1}{wc} )}{{V}_{i n}} ] . \qquad Eq . 29$$

Eq. 29, shows that putting series of diodes will decrease the distortion

For a current of 2 pA, 10 pF, p=1, and Vin=12 mV, f=100 (at sensitivity level) we have distortion of 23 nV. In audio this may be acceptable.

Distortion Source

For low Is leakage of 1 pA-10 pA, with a single diode, the impedance of the diode will be 2500 MOhm-25 GOhm (with 10 pA) at 100 Hz, and C 7002a of 10 pF, we have the impedance of 100 MOhm. This will give a voltage of 1/25 from the input and for one diode this would mean that for maximal sensitivity the distortion would be 1/25*⅛, which is pretty high. With a p diodes in series and parallel branches 7003 and 7013 we have for maximal sensitivity—assuming p=10− 1/25*⅙*(1.2/25).̂3=1/1.3M, which reflects Distortion of more than 120 dB.

Reason for Diodes in Series

There are two reasons for connecting diodes in series in each branch 7003 and 7013. The first reason is based on Eq. 22, as this connection reduces the current noise from the diode total noise current. The second reason is to divide the voltage across each diode such that the term (V/p)/25 mv will be small enough.

Reason for Parallel Branches

Parallel branches eliminate the even distortion components, as shown by equation 26.

Adaptive-SNR Ultra-Low-Power Low Noise Microphone Circuit

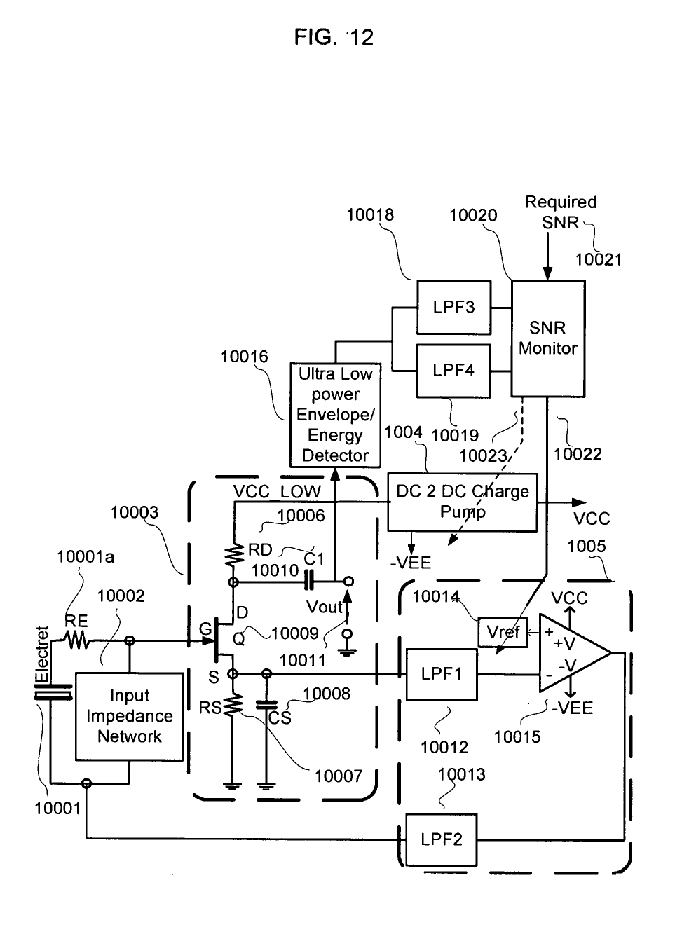

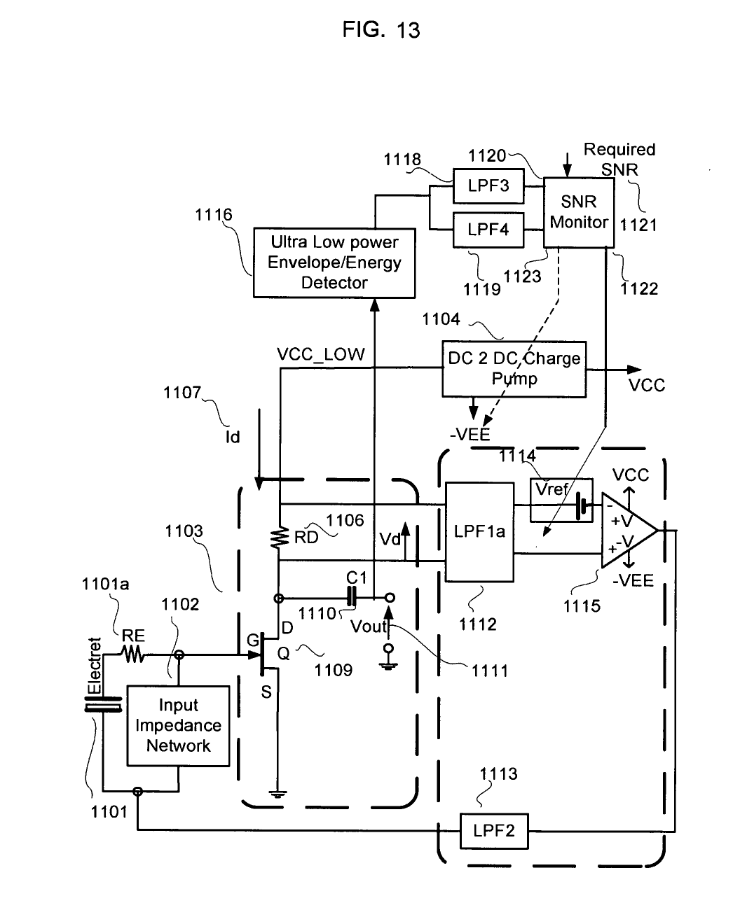

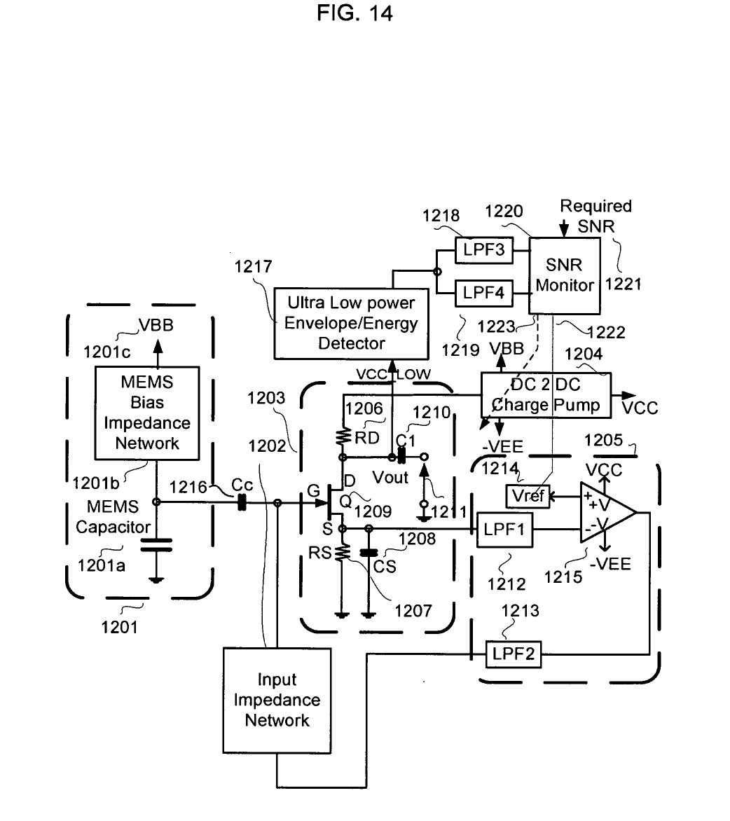

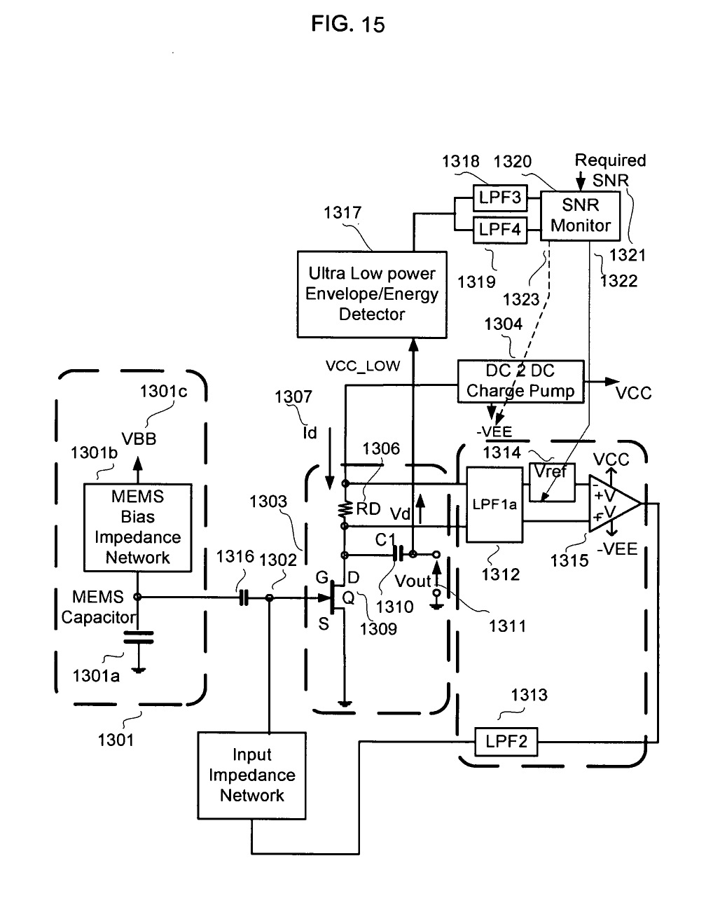

FIG. 12, FIG. 13, FIG. 14 and FIG. 15 describe an ultra-low-noise and ultra-low-power microphone circuits.

FIG. 12 is a simplified illustration of an Electret Condenser Microphone (ECM) ultra-low-noise ultra-low-power microphone with a feedback from the source gate, according to one exemplary embodiment.

FIG. 13 is a simplified illustration of an Electret Condenser Microphone (ECM) ultra-low-noise ultra-low-power microphone with a feedback from the drain gate, according to one exemplary embodiment.

FIG. 14 is a simplified illustration of a Micro Electrical Mechanical System Microphone (MEMS) ultra-low-noise ultra-low-power microphone with a feedback from the source gate, according to one exemplary embodiment.

FIG. 15 is a simplified illustration of a Micro Electrical Mechanical System Microphone ultra-low-noise ultra-low-power microphone with a feedback from the drain gate, according to one exemplary embodiment.

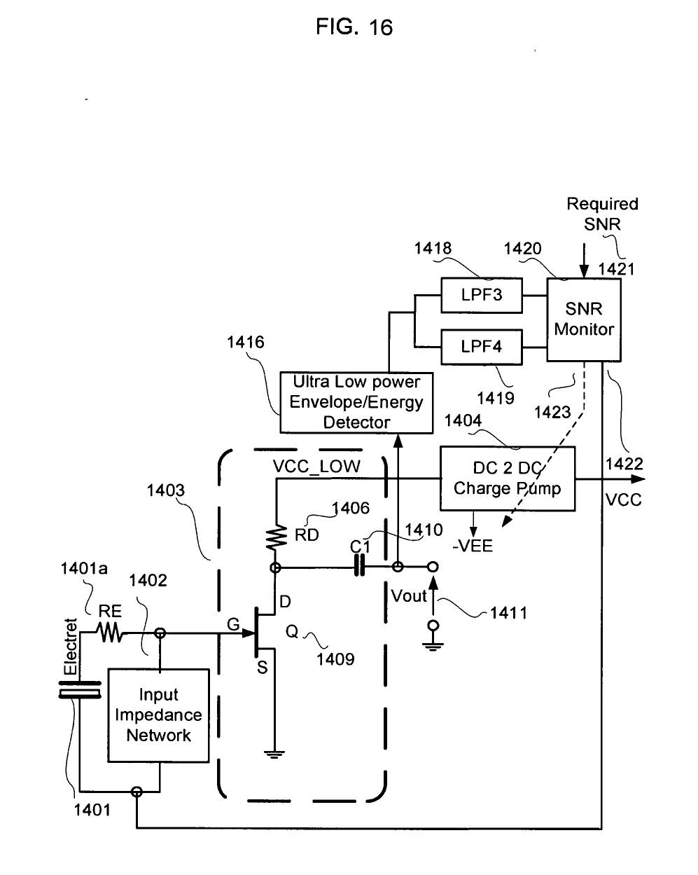

FIG. 16 is a simplified illustration of an ECM Adaptive-SNR ultra-low-power ultra-low-noise with no current feedback, according to one exemplary embodiment.

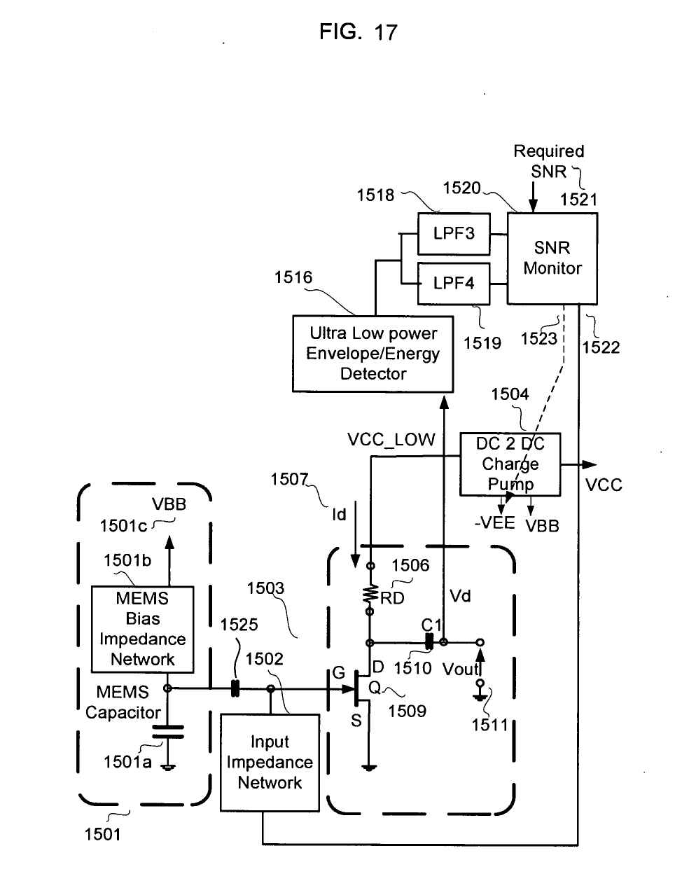

FIG. 17 is a simplified illustration of a MEMS microphone Adaptive-SNR ultra-low-power ultra-low-noise—with no current feedback, according to one exemplary embodiment.

FIG. 12 shows an adaptive-SNR ultra-low-power ultra-low-noise microphone. This microphone circuit may provide the minimum required power for the required 10021 SNR. The low noise part is achieved by using a diode based input impedance 10002, as described by FIG. 5, FIG. 6, FIG. 7 and FIG. 8. The input impedance may include a parallel capacitor C1 described as 5011, 6011, 7011 and 8011 in FIG. 5, FIG. 6, FIG. 7 and FIG. 8, respectively.

To get the low power performance a wide JFET transistors is used in which the IDSS current is high. Eq. 30 describes the relation between V_{GS} and I_{D} of the JFET 1009, of FIG. 10.

$${I}_{D} = {{I}_{DSS} ( 1 - \frac{{V}_{GS}}{{V}_{P}} )}^{2} ⇒ {g}_{m} = - \frac{2}{{V}_{P}} \sqrt{{I}_{D} {I}_{DSS}} \qquad Eq . 30$$

Recall from equation 24 given here as:

$$\begin{matrix}{v}_{n , i n}^{2} = \frac{{v}_{n , out}^{2}}{{G}^{2}} = \frac{1}{{G}^{2}} {\int }_{{f}_{1}}^{{f}_{2}} {\vert {v}_{n , out} ( f ) \vert}^{2} d \\ = 2 {I}_{S} q ( \frac{1}{4 {{π}^{2} ( C + {C}_{1} )}^{2}} ) {ξ}_{1} + \frac{8}{3 G} {KTR}_{D} {{ξ}_{2} [ \frac{( C + {C}_{1} )}{C} ]}^{2} ++ \\ {\frac{4 {KTR}_{D} {ξ}_{2}}{{G}^{2}} [ \frac{( C + {C}_{1} )}{C} ]}^{2}\end{matrix} \qquad Eq . 31$$

The reflected noise at the input may include three elements. The first element is

$$2 {I}_{S } q ( \frac{1}{4 {{π}^{2} ( C + {C}_{1} )}^{2}} ) {ξ}_{1}$$

from the PN junction of the JFET 10009 combined with the current noise of the input impedance leakage current diodes 10002. The second element is

$$\frac{8}{3 G} {KTR}_{D} {{ξ}_{2} [ \frac{( C + {C}_{1} )}{C} ]}^{2}$$

resulting from the JFET 10009 current noise between drain (D) and source (S). The third element is

$$\frac{4 {KTR}_{D} {ξ}_{2}}{{G}^{2}} [ \frac{( C + {C}_{1} )}{C} ]$$

resulting from the (RD) load resistor 10006.

The first element may be decreased using C1 5011, 6011, 7011 and 8011 in the input impedance, and may also be reduced by using JFET with ultra-low leakage. The second and third elements may be decreased by increasing the gain G. For JFET 10009 in the saturation region we have

G=gₘR_{D} Eq. 32

Therefore the second and third noise elements become:

$$\begin{matrix}\frac{8}{3 G} {KTR}_{D} {{ξ}_{2} [ \frac{( C + {C}_{1} )}{C} ]}^{2} = \frac{8}{3 {g}_{m}} KT {{ξ}_{2} [ \frac{( C + {C}_{1} )}{C} ]}^{2} & Eq . 33 \\ {\frac{4 {KTR}_{D} {ξ}_{2}}{{G}^{2}} [ \frac{( C + {C}_{1} )}{C} ]}^{2} = {\frac{4 KT}{{g}_{m}^{2} {R}_{D}} [ \frac{( C + {C}_{1} )}{C} ]}^{2} & Eq . 34\end{matrix}$$

One can see from Eq. 33 and Eq. 34 that the second and third reflected input noise depend on gm. Therefore we may want to have a large gm. One can use a wide JFET 10009, such that IDSS is extremely high, such that to get some gm,

$$\frac{2}{{V}_{P}} \sqrt{{I}_{D} {I}_{DSS}}$$

we will need to use low Id. For example, using a common microphone, a JFET transistor with Vp=1V, and IDSS=0.5 mA, with VGS=0, will give some gm0. One can use an IDSS=150 mA to 300 mA JFET with low leakage such as MX-16 of MOXTEK with VP=−8V with such transistor to get the same gm0 we need a Id=500 ua/300=1.7 ua, in order to have the JFET in saturation region we need V_{DS}≥V_{GS}−Vₚ. with such Id we have:

$${V}_{DS} \geq {V}_{GS} - {V}_{P} = \vert {V}_{P} \vert \sqrt{\frac{{I}_{D}}{{I}_{DSS}}} = \frac{\vert {V}_{P} \vert}{300} = \frac{8}{300} = 27 mv \qquad Eq . 35$$

With 1.7 μA, we also assume about 20 mV for RS 10007 and RD 10006 (10 mV each) this would mean 92 nWatt of power consumption.

The circuit of FIG. 12 includes a DC-to-DC switched capacitors voltage converter (charge pump) 10004 that receives supply voltage VCC and generates VCC_LOW, which is the voltage that drives the microphone buffer 10003. This voltage, as suggested, is about 20 mV-50 mV, with low total power consumption.

Voltage buffer 10003 may include an active element JFET 10009, which may be implemented using Metal Oxide Semiconductor FET (MOSFET) too. The buffer 10003 includes a load resistor RD 10005, which is used for amplification. Vout 10011 is taken via coupling capacitor C1 10010.

To set the required Id, which insures with the VCC_LOW that JFET 10009 is in saturation mode, a current control block 10005 is added. This current control block includes an ultra-low-power comparator 10015 and two Low Pass Filters 10012 and 10013. The filters may block the noise coming from the ultra-low-power comparator. The comparator typically consumes few nano-Amperes in a very low gain bandwidth, but may have high noise at its input (a few micro Volts) and high noise at it output. LPF1 is a bi-directional low-pass-filter that may block the noise coming from the “−” input of the ultra-low-power comparator 10015, and may allow to get a sampled voltage from the RS 10007, which transform the Id into Id*RS.

This voltage Id*RS is compared with Vref 10014 and when the feedback is voltage Vref=Id*RS hence Id=Vref/RS, if Id*Rd>Vref the comparator may generate a negative voltage that is supplied to the gate of the JFET 10009 through LPF2 and the input impedance network 10002. This negative voltage may decrease the current.

At different acoustic wave pressure at some given Id we will get different SNRs. The proposed microphone circuitry may have a control loop including an ultra-low-power envelope/energy detector 10016, LPF3 10018 and LPF4 10019 connected to the Energy/envelope detector 10016, which may generate short term average (LPF3, 10018) and long term average (LPF4 10019). The SNR is the relation between the two. The long term average may indicate the noise, while the short term average may indicate the signal. An SNR monitor circuit 10020 may analyze the long and short term averages of the envelope/energy detector 10016, and, based on the required SNR 10021, may change the Vref 10014 and hence the Id, and therefore can decease or increase Id based in the required SNR.

The input impedance network 10002 may include a diodes network as described by FIG. 5 5003, FIG. 6 6003, FIG. 7 7003 or FIG. 8 8003. As a very low current Is 5015, 6015, 7015 and 8015 is flowing through the diode network, and as the leakage Is 5015, 6015, 7015 and 8015 is the same order of the diode leakage, this may mean that each diode may have about KT/q voltage, or about 25 mV, during DC.

To have high gain, a bypass capacitor CS 10008 is added in parallel to RS 10007.

The charge pump 10004 supplies two voltages: VCC_LOW to drive the microphone buffer 10003 and −VEE for the ultra-low-power comparator 10015. The electret element 10001, which is a capacitor with a polarized element, may have high voltage on its terminals. This voltage may be discharged using the diode networks. An optional low resistor for low noise (50 Ohm-100 Ohm) RE 10001a may be added to allow a controlled discharge of the electrets element 10001 during manufacturing. This may limit the discharge current such that the diodes in the diode network 10002 may not be harmed. A parallel capacitor to the input impedance 10002 C1 such as 5011, 6011, 7011 & 8011 may be added in the input impedance. This C1 allows reduction of the noise due to the leakage current from the gate of the JFET 10009.

FIG. 13 is an improved version of the ultra-low-power ultra-low-noise microphone of FIG. 12. The circuit of FIG. 13 is similar to the one of FIG. 12, except for the feedback part. In the circuit of FIG. 13 there is no need for RS 10007 resistor and CS 10008 capacitor. Instead, the current to voltage is taken from the (RD) load resistor 1106, through LPF1a 1112. The purpose of LPF1a is to pass the voltage Id*RD to the comparator. Then −Vref 1114 is added, giving a voltage of Id*RD−Vref between the “−” and “+” terminals of the comparator 1115. If Id*RD−Vref<0, a positive voltage is created at the output of the comparator 1115, which increases the current Id 1107.

The advantage of the circuit of FIG. 13 is the reduction of the VCC_LOW by about the voltage on RS 10007. This may decrease the VCC_LOW, and hence may create a microphone buffer 1103 with a lower power consumption.

The SNR control is done as in FIG. 12, by first ultra-low-power envelope/energy detector 1116, and a two low pass filters, LPF3 1118, and LPF4 1119, an SNR monitor 1120, that according to the required SNR 1121, would generate the required Vref 1114 by signal 1122 and may optionally change VCC_LOW by signal 1123.

FIG. 14 describes a similar microphone buffer to the one of FIG. 12 using Micro Electronic Mechanical System (MEMS) microphone. The circuit is similar to the circuit of FIG. 12, except for the electret element 10001. The electret element 10001 is replaced with a MEMS unit 1201 including a MEMS bias impedance network 1201b and a MEMS capacitor 1201, which translate the acoustic wave pressure into variation in capacitance. These variations, with the assumption of constant charge on the MEMS capacitor, may be translated into voltage variations, as

$${V}_{BB} {C}_{electret} = ( {V}_{BB} + Δ V ) ( {C}_{electret} + Δ C ) ⇒ Δ V = - {V}_{BB} \frac{Δ C}{{C}_{electret}}$$

The voltage variations are coupled to the microphone buffer 1203 through Cc c-coupling capacitor 1216.

VBB is the bias voltage for the MEMS capacitor, this voltage may be positive or negative and is generated using the switch capacitor charge pump 1204, in order to generate “clean” VBB sometimes it is required to generate a higher voltage and to pass it through Low-pass-filter and a buffer—which is normally implemented using op-amplifier, the op-amplifier output is further filtered with high resistors and capacitors.

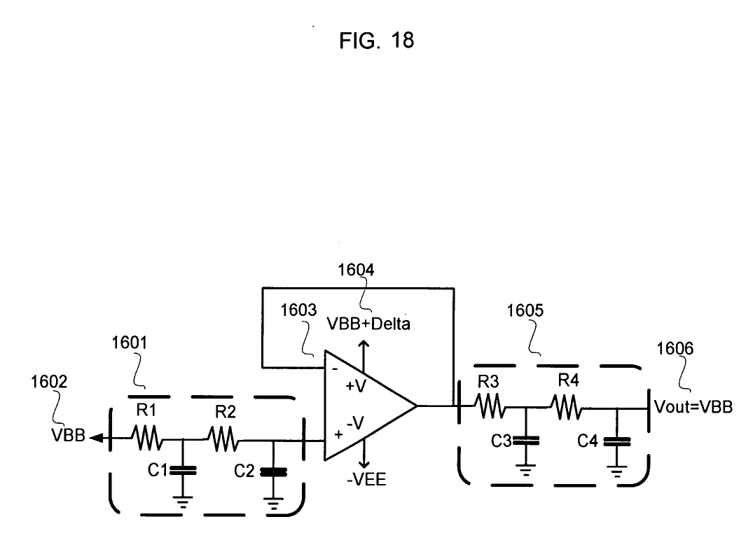

FIG. 18 is a simplified electric schematic of a circuit generating ultra-low-noise biasing voltage VBB, according to one exemplary embodiment.

The low noise VBB biasing circuit of FIG. 18 may block the noise from the VBB 1602 using LPF 1601, and pass the voltage using a unity gain amplifier 1603. The output of this amplifier, which is assumed to be low power, may have some noise that is further blocked by a second LPF 1605 the cleaned VBB is at the output 1606.

The MEMS bias impedance network 1201b is a diode network as described in FIG. 5, FIG. 6, FIG. 7 and FIGS. 8 5013, 6013, 7013 and 8013.

FIG. 15, is similar to FIG. 14 with the difference that the current feedback is taken from Rd 1306. The signal is passed through a differential low-pass-filter LPF1a 1312 and −Vref 1314 is added, similar to FIG. 13. This may decrease the required VCC_LOW generated by the charge pump 1304 and hence power consumption will be reduced.

FIG. 16 is a microphone buffer similar to the microphone buffer of FIG. 13, however, without any current control feedback (implemented by using LPF1a 1112, Vref 1114 Op-amplifier 1115 and LPF2 1113). The control of the operating point of the JFET 1409 is done by signal 1422 generated from the SNR monitor 1420. This type of circuit may not set the current exactly, but would have the advantage of setting fast the operating point. FIG. 17 is similar to FIG. 16, and is suitable for MEMS based microphones.

It is appreciated that certain features, which are, for clarity, described in the context of separate embodiments, may also be provided in combination in a single embodiment. Conversely, various features, which are, for brevity, described in the context of a single embodiment, may also be provided separately or in any suitable sub-combination.

Although descriptions have been provided above in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art.

1. A microphone comprising:
a transistor comprising at least one of a JFET and MOSFET transistor;
an impedance network, wherein a first input terminal of the impedance network is connected to a gate terminal of the transistor;
a source resistor, wherein a first terminal of the source resistor is connected to a source terminal of the transistor, and a second terminal of the source resistor is connected to a ground terminal;
a bypass capacitor (CS) connected in parallel to the source resistor;
a load resistor (RD), wherein a first terminal of the load resistor is connected to a drain terminal of the transistor;
a charge pump generating a low voltage power supply VCC_LOW and an inverted voltage −VEE, wherein the low voltage is connected to a second terminal of the load resistor, and the inverted voltage −VEE is connected to a first power supply node of an op-amplifier;
an op-amplifier, wherein
a first input terminal of the op-amplifier is connected to the source terminal of the transistor through a bi-directional low-pass-filter transistor;
a second input terminal of the op-amplifier is connected to a controlled reference voltage Vref;
a first power supply terminal of the op-amplifier is connected to the inverted voltage;
a second supply terminal of the op-amplifier is connected to the main supply voltage; and
an output terminal of the op-amplifier is connected to a second terminal of the input impedance network through a second low pass filter; and
an input electrets capacitor source connected in parallel to the input impedance network;
an ultra-low-power envelope/energy detector connected to drain terminal D of the transistor via coupling capacitor;
a third low-pass-filter connected to the output of the ultra-low-power envelope/energy detector; and
a fourth low-pass-filter connected to the output of the ultra-low-power envelope/energy detector.

2. An SNR monitor comprising:
a first input connected to a third low-pass-filter output;
a second input connected to a fourth low-pass-filter output;
one of: a third analog input, and a third digital input, that determines the required SNR:
a first output connected to a control input of a controlled Vref; and
an optional second output connected to a control input of an optional controlled charge pump.

3. A microphone comprising:
a transistor comprising at least one of a JFET and MOSFET transistor;
an impedance network, wherein a first input terminal of the impedance network is connected to a gate terminal of the transistor;
a source resistor, wherein a first terminal of the source resistor is connected to a source terminal of the transistor, and a second terminal of the source resistor is connected to a ground terminal;
a bypass capacitor (CS) connected in parallel to the source resistor;
a load resistor (RD), wherein a first terminal of the load resistor is connected to a drain terminal of the transistor;
a charge pump generating a low voltage power supply VCC_LOW and an inverted voltage −VEE, wherein the low voltage is connected to a second terminal of the load resistor, and the inverted voltage −VEE is connected to a first power supply node of an op-amplifier;
an op-amplifier, wherein
a first input terminal of the op-amplifier is connected to the source terminal of the transistor through a bi-directional low-pass-filter transistor;
a second input terminal of the op-amplifier is connected to a controlled reference voltage Vref;
a first power supply of the op-amplifier terminal is connected to the inverted voltage;
a second supply terminal of the op-amplifier is connected to the main supply voltage; and
an output terminal of the op-amplifier is connected to a second terminal of the input impedance network through a second low pass filter; and
an input source comprising:
a MEMS capacitor, wherein a first terminal of the MEMS capacitor is connected to ground, and a second terminal of the MEMS capacitor is connected to a first terminal of a MEMS bias network;
the MEMS bias network, wherein a second terminal of the MEMS bias network is connected to a bias voltage VBB; and
a coupling capacitor, wherein a first terminal of the coupling capacitor is connected to the second terminal of the MEMS capacitor, and with a second terminal of the coupling capacitor is connected to the gate terminal of the transistor;
an ultra-low-power envelope/energy detector connected to drain terminal of the transistor via a coupling capacitor;
a third low-pass-filter connected to the output of the ultra-low-power envelope/energy detector; and
a fourth low-pass-filter connected to the output of the ultra-low-power envelope/energy detector.

4. A microphone comprising:
a transistor comprising at least one of a JFET and MOSFET transistor;
an impedance network, wherein a first input terminal of the impedance network is connected to a gate terminal of the transistor;
a source resistor, wherein a first terminal of the source resistor is connected to a source terminal of the transistor, and a second terminal of the source resistor is connected to a ground terminal;
a bypass capacitor (CS) connected in parallel to the source resistor;
a load resistor (RD), wherein a first terminal of the load resistor is connected to a drain terminal of the transistor;
a charge pump generating a low voltage power supply VCC_LOW and an inverted voltage −VEE, wherein the low voltage is connected to a second terminal of the load resistor, and the inverted voltage −VEE is connected to a first power supply node of an op-amplifier;
the op-amplifier, wherein
a first input terminal of the op-amplifier is connected to a controlled reference voltage connected to first output terminal of a differential bi-directional low-pass-filter, wherein a first input terminal of the differential bi-directional low-pass-filter is connected to a second terminal of the load resistor;
a second input terminal of the op-amplifier is connected to a second output terminal of a differential bi-directional low-pass-filter, wherein a second input terminal of the differential bi-directional low-pass-filter is connected to the first terminal of the load resistor;
a first power supply of the op-amplifier terminal is connected to the inverted voltage;
a second supply terminal of the op-amplifier is connected to the main supply voltage; and
an output terminal of the op-amplifier is connected to a second terminal of the input impedance network through a second low pass filter;
an input electrets capacitor source connected in parallel to the input impedance network;
an ultra-low-power envelope/energy detector connected to drain terminal of the transistor via a coupling capacitor;
a third low-pass-filter connected to the output of the ultra-low-power envelope/energy detector; and
a fourth low-pass-filter connected to the output of the ultra-low-power envelope/energy detector.

5. A microphone comprising:
a transistor comprising at least one of a JFET and MOSFET transistor;
an impedance network, wherein a first input terminal of the impedance network is connected to a gate terminal of the transistor;
a source resistor, wherein a first terminal of the source resistor is connected to a source terminal of the transistor, and a second terminal of the source resistor is connected to a ground terminal;
a bypass capacitor (CS) connected in parallel to the source resistor;
a load resistor (RD), wherein a first terminal of the load resistor is connected to a drain terminal of the transistor;
a charge pump generating a low voltage power supply VCC_LOW and an inverted voltage −VEE, wherein the low voltage is connected to a second terminal of the load resistor, and the inverted voltage −VEE is connected to a first power supply node of an op-amplifier;
an op-amplifier, wherein
a first input terminal of the op-amplifier is connected to a controlled reference voltage connected to first output terminal of a differential bi-directional low-pass-filter, wherein a first input terminal of the differential bi-directional low-pass-filter is connected to a second terminal of the load resistor;
a second input terminal of the op-amplifier is connected to a second output terminal of a differential bi-directional low-pass-filter, wherein a second input terminal of the differential bi-directional low-pass-filter is connected to the first terminal of the load resistor;
a first power supply of the op-amplifier terminal is connected to the inverted voltage;
a second supply terminal of the op-amplifier is connected to the main supply voltage; and
an output terminal of the op-amplifier is connected to a second terminal of the input impedance network through a second low pass filter; and
an input source comprising:
a MEMS capacitor, wherein a first terminal of the MEMS capacitor is connected to ground and a second terminal of the MEMS capacitor is connected to a first terminal of a MEMS bias network;
a MEMS bias network connected with it second terminal to a bias voltage VBB; and
the MEMS bias network, wherein a second terminal of the MEMS bias network is connected to a bias voltage VBB; and
a coupling capacitor, wherein a first terminal of the coupling capacitor is connected to the second terminal of the MEMS capacitor, and with a second terminal of the coupling capacitor is connected to the gate terminal of the transistor.

6. The microphone according to any of claim 1, wherein the input impedance network comprises:
a plurality of low-leakage diodes connected in series wherein:
a first diode cathode terminal is the first terminal of the input impedance network;
a first diode anode terminal is connected to a second diode cathode terminal; and
an anode terminal of diode N is the second terminal to the input impedance network.

7. The microphone according to claim 1, wherein the input impedance network is comprises a plurality of low-leakage diodes connected in series wherein:
a first diode anode terminal is the first terminal of the input impedance network;
a first diode cathode terminal is connected to a second diode anode terminal; and
a cathode terminal of diode N is the second terminal of the input impedance network.

8. The microphone according to claim 1, wherein the input impedance network comprises of a parallel diode network comprising:
a first diode network comprising a plurality of diodes connected in series wherein
a first diode cathode terminal is the first terminal of the input impedance network;
a first diode anode terminal is connected to a second diode cathode terminal; and
an anode terminal of diode N is the second terminal of the input impedance network; and
a second diode network comprising a plurality of diodes connected in series wherein:
a first diode anode terminal is the first terminal of the input impedance network;
a first diode cathode terminal is connected to a second diode anode terminal; and
a cathode terminal of diode N is the second terminal to the input impedance network.

9. The microphone according to claim 1, wherein the input impedance network comprises at least two series of two-terminal sub-networks wherein:
a first terminal of a first sub-network is the first terminal of the input impedance network;
a second terminal of a last sub network is the second terminal of the input impedance network and
wherein a sub-network comprises a two low-leakage identical diodes connected in parallel in opposite polarity.

10. The microphone according to claim 1,
wherein the charge pump is controlled.

11. The microphone according to claim 2, wherein the MEMS bias impedance network comprises a plurality of low-leakage diodes connected in series, wherein:
a first diode cathode terminal is the first terminal of the MEMS bias impedance network;
a first diode anode terminal is connected to a second diode cathode terminal; and
an anode terminal of diode N is the second terminal to the MEMS bias impedance network.

12. The microphone according to claim 2, wherein the MEMS bias impedance network comprises plurality of low-leakage diodes connected in series, wherein:
a first diode anode terminal is the first terminal of the MEMS bias impedance network;
a first diode cathode terminal is connected to a second diode anode terminal; and
a cathode terminal of diode N is the second terminal to the MEMS bias impedance network.

13. The microphone according to claim 2, wherein the MEMS bias impedance network comprises a parallel diode network comprising:
a first diode network comprising a plurality of diodes connected in series, wherein
a first diode cathode terminal is the first terminal of the MEMS bias impedance network;
a first diode anode terminal is connected to a second diode cathode terminal;
an anode terminal of diode N is the second terminal of the MEMS bias impedance network; and
a second diode network comprising a plurality of diodes connected in series, wherein
a first diode anode terminal is the first terminal of the MEMS bias impedance network;
a first diode cathode terminal is connected to a second diode anode terminal; and
a cathode terminal of diode N is the second terminal to the MEMS bias impedance network.

14. The microphone according to claim 2, wherein the MEMS bias impedance network comprises of at least two series of two-terminal sub-networks wherein a first terminal of a first sub-network is the first terminal of the MEMS bias impedance network and a second terminal of a last sub network is the second terminal of the MEMS bias impedance network, wherein a sub network s comprises two low-leakage identical diodes connected in parallel in opposite polarity.

15. A method for sensing an acoustic signal, the method comprising:
connecting a first input terminal of an impedance network to a gate terminal of a transistor comprising at least one of a JFET and MOSFET transistor;
connecting a first terminal of a source resistor to a source terminal of the transistor, and a second terminal of the source resistor to a ground terminal;
connecting a bypass capacitor (CS) in parallel with the source resistor;
connecting a first terminal of a load resistor (RD) to a drain terminal of the transistor;
connecting a charge pump generating a low voltage power supply VCC_LOW and an inverted voltage −VEE, wherein the low voltage is connected to a second terminal of the load resistor, and the inverted voltage −VEE is connected to a first power supply node of an op-amplifier;
connecting a first input terminal of the op-amplifier to the source terminal of the transistor through a bi-directional low-pass-filter transistor;
connecting a second input terminal of the op-amplifier to a controlled reference voltage Vref;
connecting a first power supply terminal of the op-amplifier to the inverted voltage;
connecting a second supply terminal of the op-amplifier to the main supply voltage; and
connecting an output terminal of the op-amplifier to a second terminal of the input impedance network through a second low pass filter; and
connecting an input electrets capacitor source in parallel with the input impedance network;
connecting an ultra-low-power envelope/energy detector to drain terminal D of the transistor via coupling capacitor;
connecting a third low-pass-filter to the output of the ultra-low-power envelope/energy detector; and
connecting a fourth low-pass-filter to the output of the ultra-low-power envelope/energy detector.

16. An SNR monitor comprising:
a first input connected to a third low-pass-filter output;
a second input connected to a fourth low-pass-filter output;
one of: a third analog input, and a third digital input, that determines the required SNR:
a first output connected to a control input of a controlled Vref; and
an optional second output connected to a control input of an optional controlled charge pump.

17. A method for sensing an acoustic signal, the method comprising:
connecting a first input terminal of an impedance network to a gate terminal of a transistor comprising at least one of a JFET and MOSFET transistor;
connecting a first terminal of a source resistor to a source terminal of the transistor, and a second terminal of the source resistor to a ground terminal;
connecting a bypass capacitor (CS) in parallel with the source resistor;
connecting a first terminal of a load resistor (RD) to a drain terminal of the transistor;
connecting a charge pump generating a low voltage power supply VCC_LOW and an inverted voltage −VEE, wherein the low voltage is connected to a second terminal of the load resistor, and the inverted voltage −VEE is connected to a first power supply node of an op-amplifier;
connecting a first input terminal of the op-amplifier to the source terminal of the transistor through a bi-directional low-pass-filter transistor;
connecting a second input terminal of the op-amplifier to a controlled reference voltage Vref;
connecting a first power supply terminal of the op-amplifier to the inverted voltage;
connecting a second supply terminal of the op-amplifier to the main supply voltage; and
connecting an output terminal of the op-amplifier to a second terminal of the input impedance network through a second low pass filter; and
connecting an input source comprising:
a MEMS capacitor, wherein a first terminal of the MEMS capacitor is connected to ground, and a second terminal of the MEMS capacitor is connected to a first terminal of a MEMS bias network;
the MEMS bias network, wherein a second terminal of the MEMS bias network is connected to a bias voltage VBB; and
a coupling capacitor, wherein a first terminal of the coupling capacitor is connected to the second terminal of the MEMS capacitor, and with a second terminal of the coupling capacitor is connected to the gate terminal of the transistor.
connecting an ultra-low-power envelope/energy detector to drain terminal of the transistor via a coupling capacitor;
connecting a third low-pass-filter to the output of the ultra-low-power envelope/energy detector; and
connecting a fourth low-pass-filter to the output of the ultra-low-power envelope/energy detector;

18. A method for sensing an acoustic signal, the method comprising:
connecting a first input terminal of an impedance network to a gate terminal of a transistor comprising at least one of a JFET and MOSFET transistor;
connecting a first terminal of a source resistor to a source terminal of the transistor, and a second terminal of the source resistor to a ground terminal;
connecting a bypass capacitor (CS) in parallel with the source resistor;
connecting a first terminal of a load resistor (RD) to a drain terminal of the transistor;
connecting a charge pump generating a low voltage power supply VCC_LOW and an inverted voltage −VEE, wherein the low voltage is connected to a second terminal of the load resistor, and the inverted voltage −VEE is connected to a first power supply node of an op-amplifier;
connecting a first input terminal of the op-amplifier to a controlled reference voltage connected to first output terminal of a differential bi-directional low-pass-filter;
connecting a first input terminal of the differential bi-directional low-pass-filter to a second terminal of the load resistor;
connecting a second input terminal of the op-amplifier to a second output terminal of a differential bi-directional low-pass-filter;
connecting a second input terminal of the differential bi-directional low-pass-filter to the first terminal of the load resistor;
connecting a first power supply of the op-amplifier terminal to the inverted voltage;
connecting a second supply terminal of the op-amplifier to the main supply voltage;
connecting an output terminal of the op-amplifier to a second terminal of the input impedance network through a second low pass filter;
connecting an input electrets capacitor source in parallel to the input impedance network;
connecting an ultra-low-power envelope/energy detector to drain terminal D of the transistor via a coupling capacitor;
connecting a third low-pass-filter to the output of the ultra-low-power envelope/energy detector; and
connecting a fourth low-pass-filter connected to the output of the ultra-low-power envelope/energy detector.

19. A method for sensing an acoustic signal, the method comprising:
connecting a first input terminal of an impedance network to a gate terminal of a transistor comprising at least one of a JFET and MOSFET transistor;
connecting a first terminal of a source resistor to a source terminal of the transistor, and a second terminal of the source resistor to a ground terminal;
connecting a bypass capacitor (CS) in parallel with the source resistor;
connecting a first terminal of a load resistor (RD) to a drain terminal of the transistor;
connecting a charge pump generating a low voltage power supply VCC_LOW and an inverted voltage −VEE, wherein the low voltage is connected to a second terminal of the load resistor, and the inverted voltage −VEE is connected to a first power supply node of an op-amplifier;
connecting a first input terminal of the op-amplifier to a controlled reference voltage connected to first output terminal of a differential bi-directional low-pass-filter;
connecting a first input terminal of the differential bi-directional low-pass-filter to a second terminal of the load resistor;
connecting a second input terminal of the op-amplifier to a second output terminal of a differential bi-directional low-pass-filter;
connecting a second input terminal of the differential bi-directional low-pass-filter to the first terminal of the load resistor;
connecting a first power supply of the op-amplifier terminal to the inverted voltage;
connecting a second supply terminal of the op-amplifier to the main supply voltage;
connecting an output terminal of the op-amplifier to a second terminal of the input impedance network through a second low pass filter; and
connecting an input source comprising:
a MEMS capacitor, wherein a first terminal of the MEMS capacitor is connected to ground and a second terminal of the MEMS capacitor is connected to a first terminal of a MEMS bias network;
a MEMS bias network connected with it second terminal to a bias voltage VBB; and
the MEMS bias network, wherein a second terminal of the MEMS bias network is connected to a bias voltage VBB; and
a coupling capacitor, wherein a first terminal of the coupling capacitor is connected to the second terminal of the MEMS capacitor, and with a second terminal of the coupling capacitor is connected to the gate terminal of the transistor.

20. The microphone according to claim 4, wherein the MEMS bias impedance network comprises a plurality of low-leakage diodes connected in series, wherein:
a first diode cathode terminal is the first terminal of the MEMS bias impedance network;
a first diode anode terminal is connected to a second diode cathode terminal; and
an anode terminal of diode N is the second terminal to the MEMS bias impedance network.

21. The microphone according to claim 4, wherein the MEMS bias impedance network comprises plurality of low-leakage diodes connected in series, wherein:
a first diode anode terminal is the first terminal of the MEMS bias impedance network;
a first diode cathode terminal is connected to a second diode anode terminal; and
a cathode terminal of diode N is the second terminal to the MEMS bias impedance network.

22. The microphone according to claim 4, wherein the MEMS bias impedance network comprises a parallel diode network comprising:
a first diode network comprising a plurality of diodes connected in series, wherein
a first diode cathode terminal is the first terminal of the MEMS bias impedance network;
a first diode anode terminal is connected to a second diode cathode terminal;
an anode terminal of diode N is the second terminal of the MEMS bias impedance network; and
a second diode network comprising a plurality of diodes connected in series, wherein
a first diode anode terminal is the first terminal of the MEMS bias impedance network;
a first diode cathode terminal is connected to a second diode anode terminal; and
a cathode terminal of diode N is the second terminal to the MEMS bias impedance network.

23. The microphone according to claim 4, wherein the MEMS bias impedance network comprises of at least two series of two-terminal sub-networks wherein a first terminal of a first sub-network is the first terminal of the MEMS bias impedance network and a second terminal of a last sub network is the second terminal of the MEMS bias impedance network, wherein a sub network s comprises two low-leakage identical diodes connected in parallel in opposite polarity.

24. The microphone according to claim 2, wherein the input impedance network comprises:
a plurality of low-leakage diodes connected in series wherein:
a first diode cathode terminal is the first terminal of the input impedance network;
a first diode anode terminal is connected to a second diode cathode terminal; and
an anode terminal of diode N is the second terminal to the input impedance network.

25. The microphone according to claim 2, wherein the input impedance network is comprises a plurality of low-leakage diodes connected in series wherein:
a first diode anode terminal is the first terminal of the input impedance network;
a first diode cathode terminal is connected to a second diode anode terminal; and
a cathode terminal of diode N is the second terminal of the input impedance network.

26. The microphone according to claim 2, wherein the input impedance network comprises of a parallel diode network comprising:
a first diode network comprising a plurality of diodes connected in series wherein
a first diode cathode terminal is the first terminal of the input impedance network;
a first diode anode terminal is connected to a second diode cathode terminal; and
an anode terminal of diode N is the second terminal of the input impedance network; and
a second diode network comprising a plurality of diodes connected in series wherein:
a first diode anode terminal is the first terminal of the input impedance network;
a first diode cathode terminal is connected to a second diode anode terminal; and
a cathode terminal of diode N is the second terminal to the input impedance network.

27. The microphone according to claim 2, wherein the input impedance network comprises at least two series of two-terminal sub-networks wherein:
a first terminal of a first sub-network is the first terminal of the input impedance network;
a second terminal of a last sub network is the second terminal of the input impedance network and
wherein a sub-network comprises a two low-leakage identical diodes connected in parallel in opposite polarity.

28. The microphone according to claim 2, wherein the charge pump is controlled.

29. The microphone according to claim 3, wherein the input impedance network comprises:
a plurality of low-leakage diodes connected in series wherein:
a first diode cathode terminal is the first terminal of the input impedance network;
a first diode anode terminal is connected to a second diode cathode terminal; and
an anode terminal of diode N is the second terminal to the input impedance network.

30. The microphone according to claim 3, wherein the input impedance network is comprises a plurality of low-leakage diodes connected in series wherein:
a first diode anode terminal is the first terminal of the input impedance network;
a first diode cathode terminal is connected to a second diode anode terminal; and
a cathode terminal of diode N is the second terminal of the input impedance network.

31. The microphone according to claim 3, wherein the input impedance network comprises of a parallel diode network comprising:
a first diode network comprising a plurality of diodes connected in series wherein
a first diode cathode terminal is the first terminal of the input impedance network;
a first diode anode terminal is connected to a second diode cathode terminal; and
an anode terminal of diode N is the second terminal of the input impedance network; and
a second diode network comprising a plurality of diodes connected in series wherein:
a first diode anode terminal is the first terminal of the input impedance network;
a first diode cathode terminal is connected to a second diode anode terminal; and
a cathode terminal of diode N is the second terminal to the input impedance network.

32. The microphone according to claim 3, wherein the input impedance network comprises at least two series of two-terminal sub-networks wherein:
a first terminal of a first sub-network is the first terminal of the input impedance network;
a second terminal of a last sub network is the second terminal of the input impedance network and
wherein a sub-network comprises a two low-leakage identical diodes connected in parallel in opposite polarity.

33. The microphone according to claim 3, wherein the charge pump is controlled.

34. The microphone according to claim 4, wherein the input impedance network comprises:
a plurality of low-leakage diodes connected in series wherein:
a first diode cathode terminal is the first terminal of the input impedance network;
a first diode anode terminal is connected to a second diode cathode terminal; and
an anode terminal of diode N is the second terminal to the input impedance network.

35. The microphone according to claim 4, wherein the input impedance network is comprises a plurality of low-leakage diodes connected in series wherein:
a first diode anode terminal is the first terminal of the input impedance network;
a first diode cathode terminal is connected to a second diode anode terminal; and
a cathode terminal of diode N is the second terminal of the input impedance network.

36. The microphone according to claim 4, wherein the input impedance network comprises of a parallel diode network comprising:
a first diode network comprising a plurality of diodes connected in series wherein
a first diode cathode terminal is the first terminal of the input impedance network;
a first diode anode terminal is connected to a second diode cathode terminal; and
an anode terminal of diode N is the second terminal of the input impedance network; and
a second diode network comprising a plurality of diodes connected in series wherein:
a first diode anode terminal is the first terminal of the input impedance network;
a first diode cathode terminal is connected to a second diode anode terminal; and
a cathode terminal of diode N is the second terminal to the input impedance network.

37. The microphone according to claim 4, wherein the input impedance network comprises at least two series of two-terminal sub-networks wherein:
a first terminal of a first sub-network is the first terminal of the input impedance network;
a second terminal of a last sub network is the second terminal of the input impedance network and
wherein a sub-network comprises a two low-leakage identical diodes connected in parallel in opposite polarity.

38. The microphone according to claim 4, wherein the charge pump is controlled.
